(19) United States
(12) Patent Application Publication
(10) Pub. No.: US 2024/0347905 A1
(43) Pub. Date: Oct. 17, 2024

(54) RADIO FREQUENCY MODULE, MANUFACTURING METHOD OF RADIO FREQUENCY MODULE, AND COMMUNICATION DEVICE

(71) Applicant: Murata Manufacturing Co., Ltd., Nagaokakyo-shi (JP)

(72) Inventors: Mayuka ONO, Nagaokakyo-shi (JP); Motoji TSUDA, Nagaokakyo-shi (JP)

(73) Assignee: Murata Manufacturing Co., Ltd., Nagaokakyo-shi (JP)

(21) Appl. No.: 18/751,626

(22) Filed: Jun. 24, 2024

Related U.S. Application Data
(63) Continuation of application No. PCT/JP2022/045878, filed on Dec. 13, 2022.

(30) Foreign Application Priority Data
Jan. 20, 2022 (JP) 2022-007480

(51) Int. Cl. H01Q 1/52; H01Q 1/02; H01Q 21/06

(52) U.S. Cl. CPC H01Q 1/526; H01Q 1/02; H01Q 21/065

(57) ABSTRACT

A radio frequency module that can improve heat dissipation properties and shielding properties is provided. In a radio frequency module, an electronic component has a main surface on an opposite side of a mounting board side and an outer peripheral surface. A resin layer covers at least a part of the outer peripheral surface of the electronic component. A metal electrode layer covers the main surface of the electronic component and a main surface of the resin layer on the opposite side of the mounting board side. In plan view from a thickness direction of a mounting board, an outer edge of the main surface of the electronic component is located on an inner side of an outer edge of the electronic component. The electronic component further has an inclined surface.

### CROSS-REFERENCE TO RELATED APPLICATIONS

This is a continuation application of PCT/JP2022/045878 filed on Dec. 13, 2022, designating the United States of America, which is based on and claims priority to Japanese Patent Application No. JP 2022-007480 filed on Jan. 20, 2022. The entire contents of the above-identified applications, including the specifications, drawings and claims, are incorporated herein by reference in their entirety.

### TECHNICAL FIELD

The present disclosure generally relates to a radio frequency module, a manufacturing method of the radio frequency module, and a communication device and, more particularly, to a radio frequency module including a mounting board and an electronic component disposed at the mounting board, a manufacturing method of the radio frequency module, and a communication device including the radio frequency module.

### BACKGROUND ART

Patent Document 1 discloses a radio frequency module including a substrate (mounting board), an electronic component provided on the substrate, an insulating layer (resin layer) that covers a part of a side surface of the electronic component, and a heat dissipation layer that covers at least a top surface of the electronic component and the side surface of the electronic component excluding the part of the side surface. In the radio frequency module disclosed in Patent Document 1, since the heat dissipation layer is made of metal, the electronic component can be shielded from noise due to an external magnetic field or the like.

### CITATION LIST

### Patent Document

Patent Document 1: International Publication No. WO2018/092529

### SUMMARY OF DISCLOSURE

### Technical Problem

In the radio frequency module disclosed in Patent Document 1, it is desired to improve heat dissipation properties and shielding properties.

An object of the present disclosure is to provide a radio frequency module that can improve heat dissipation properties and shielding properties, a manufacturing method of the radio frequency module, and a communication device.

### Solution to Problem

According to an aspect of the present disclosure, a radio frequency module includes a mounting board, an electronic component, a resin layer, and a metal electrode layer. The mounting board has a first main surface and a second main surface facing each other. The electronic component is disposed at the first main surface of the mounting board. The electronic component has a main surface on an opposite side of a mounting board side and an outer peripheral surface. The resin layer is disposed at the first main surface of the mounting board. The resin layer covers at least a part of the outer peripheral surface of the electronic component. The metal electrode layer covers the main surface of the electronic component and a main surface of the resin layer on the opposite side of the mounting board side. In plan view from a thickness direction of the mounting board, an outer edge of the main surface of the electronic component is located on an inner side of an outer edge of the electronic component. The electronic component further has an inclined surface. The inclined surface connects the main surface of the electronic component and the outer peripheral surface of the electronic component. The metal electrode layer is disposed across the main surface of the electronic component, the inclined surface of the electronic component, and the main surface of the resin layer.

According to an aspect of the present disclosure, a manufacturing method of a radio frequency module includes a first step, a second step, and a third step. In the first step, a mounting structural body is prepared. The mounting structural body includes a mounting board having a first main surface and a second main surface facing each other, an electronic component disposed at the first main surface of the mounting board, and a resin structural body that is disposed at the first main surface of the mounting board and covers the electronic component. In the second step, the mounting structural body is ground from a side of the resin structural body opposite to a mounting board side by blast processing to expose a main surface of the electronic component on an opposite side of the mounting board side and to form a resin layer formed by a part of the resin structural body. In the third step, a metal electrode layer that covers the electronic component and the resin layer is formed. In the second step, an inclined surface that connects the main surface and an outer peripheral surface of the electronic component is formed at the electronic component, and the electronic component and the resin structural body of the mounting structural body are ground such that a shortest distance between a main surface of the resin layer on the opposite side of the mounting board side and the mounting board is shorter than a shortest distance between the main surface of the electronic component and the mounting board.

According to an aspect of the present disclosure, a communication device includes the radio frequency module according to the above aspect, and a signal processing circuit. The signal processing circuit is connected to the radio frequency module.

### Advantageous Effects of Disclosure

According to the aspects of the present disclosure, the radio frequency module, the manufacturing method of the radio frequency module, and the communication device can improve the heat dissipation properties and the shielding properties.

### BRIEF DESCRIPTION OF DRAWINGS

FIG. 1 is a sectional view of a radio frequency module according to an embodiment.

FIG. 2 is a plan view of the radio frequency module.

FIG. 3A is a plan view obtained by breaking a part of the radio frequency module.

FIG. 3B illustrates the radio frequency module and is a sectional view taken along line X-X of FIG. 3A.

FIG. 3C illustrates the radio frequency module and is a partially enlarged view of FIG. 3B.

FIG. 4 is an explanatory view of colors in plan view of the radio frequency module.

FIG. 5 is a sectional view obtained by breaking a part of the radio frequency module.

FIGS. 6A to 6D are step sectional views for describing a manufacturing method of the radio frequency module.

FIG. 7 is a circuit configuration diagram of a communication device including the radio frequency module.

FIG. 8 is a sectional view illustrating another example 1 of an electronic component in the radio frequency module.

FIG. 9 is a sectional view illustrating another example 2 of an electronic component in the radio frequency module.

FIG. 10 is a sectional view illustrating another example 3 of an electronic component in the radio frequency module.

### DESCRIPTION OF EMBODIMENTS

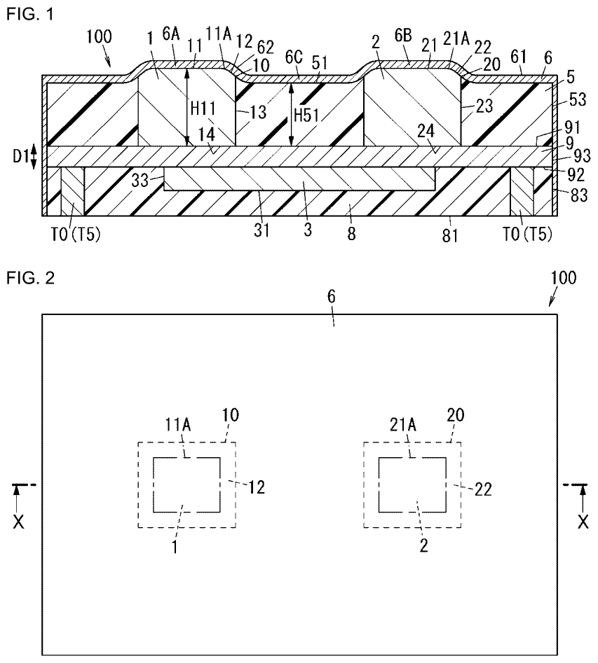

FIGS. 1 to 5, 6A to 6D, 8, 9, and 10, which are referred to in the following embodiment or the like, are all schematic views, and each of ratios of sizes or thicknesses of each constituent element in the drawing does not necessarily reflect the actual dimensional ratio.

### Embodiment

### (1) Outline

As illustrated in FIG. 1, a radio frequency module 100 according to an embodiment includes a mounting board 9, an electronic component 1, a resin layer 5, and a metal electrode layer 6. The mounting board 9 has a first main surface 91 and a second main surface 92 that face each other. Here, “facing” means facing geometrically rather than physically. The electronic component 1 is disposed at the first main surface 91 of the mounting board 9. The electronic component 1 has a main surface 11 on an opposite side of the mounting board 9 side and an outer peripheral surface 13. The resin layer 5 is disposed at the first main surface 91 of the mounting board 9. The resin layer 5 covers at least a part of the outer peripheral surface 13 of the electronic component 1. The metal electrode layer 6 covers the main surface 11 of the electronic component 1 and a main surface 51 of the resin layer 5 on the opposite side of the mounting board 9 side. In plan view from a thickness direction D1 of the mounting board 9, an outer edge 11A of the main surface 11 of the electronic component 1 is located on an inner side of an outer edge 10 of the electronic component 1. The electronic component 1 further has an inclined surface 12. The inclined surface 12 connects the main surface 11 of the electronic component 1 and the outer peripheral surface 13 of the electronic component 1. The metal electrode layer 6 is disposed across the main surface 11 of the electronic component 1, the inclined surface 12 of the electronic component 1, and the main surface 51 of the resin layer 5. The term “radio frequency module” used in the present specification refers to a module used for communication of a radio frequency signal, the module including a mounting board and at least one electronic component mounted on the mounting board.

In addition, the radio frequency module 100 further includes a second electronic component 2 that is separate from the electronic component 1 (also referred to as a first electronic component 1 below). The second electronic component 2 is disposed at the first main surface 91 of the mounting board 9.

In addition, the radio frequency module 100 further includes a plurality of external connection terminals TO. The plurality of external connection terminals TO are disposed at the second main surface 92 of the mounting board 9.

In addition, the radio frequency module 100 further includes a third electronic component 3 that is separate from the first electronic component 1. The third electronic component 3 is disposed at the second main surface 92 of the mounting board 9.

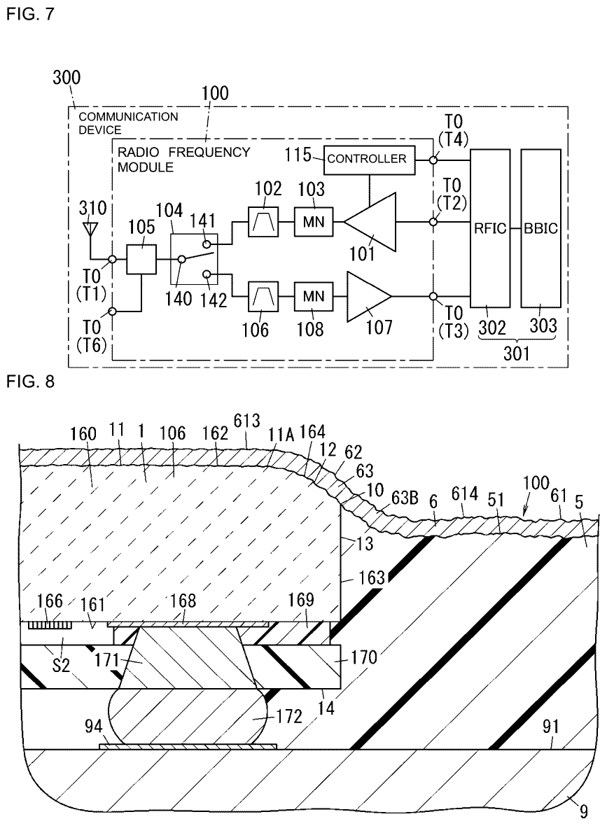

The radio frequency module 100 is used, for example, in a communication device 300 as illustrated in FIG. 7. The communication device 300 is, for example, but not limited to, a mobile phone (for example, a smartphone) and may be, for example, a wearable terminal (for example, a smartwatch), or the like. The radio frequency module 100 is, for example, a module that can support a fourth generation mobile communication (4G) standard or a fifth generation mobile communication (5G) standard. The 4G standard is, for example, a third generation partnership project (3GPP: registered trademark) long term evolution (LTE: registered trademark) standard. The 5G standard is, for example, the 5G new radio (NR).

The radio frequency module 100 and the manufacturing method thereof according to the embodiment will be described below with reference to FIGS. 1 to 7, and the communication device 300 will be described in more detail with reference to FIG. 7.

### (2) Radio Frequency Module

### (2.1) Circuit Configuration of Radio Frequency Module

A circuit configuration of the radio frequency module 100 according to the embodiment will be described with reference to FIG. 7.

The radio frequency module 100 is configured to, for example, be able to amplify a transmission signal input from a signal processing circuit 301 and output the amplified transmission signal to an antenna 310. The radio frequency module 100 is further configured to, for example, be able to amplify a reception signal input from the antenna 310 and output the amplified reception signal to the signal processing circuit 301. The signal processing circuit 301 is not a constituent element of the radio frequency module 100, but a constituent element of the communication device 300 including the radio frequency module 100. The radio frequency module 100 according to the embodiment is controlled by, for example, the signal processing circuit 301 of the communication device 300. The communication device 300 includes the radio frequency module 100 and the signal processing circuit 301. The communication device 300 further includes the antenna 310. The communication device 300 further includes a circuit board on which the radio frequency module 100 is mounted. The circuit board is, for example, a printed wiring board. The circuit board has a ground electrode to which a ground potential is applied.

As illustrated in FIG. 7, the radio frequency module 100 includes a transmission filter 102, a reception filter 106, a power amplifier 101, an output matching circuit 103, a controller 115, a low-noise amplifier 107, an input matching circuit 108, a switch 104, and a coupler 105. In the radio frequency module 100, for example, the transmission filter 102 constitutes the first electronic component 1 (see FIG. 1) described above. Thus, the first electronic component 1 is a transmission circuit component provided in a signal path of a transmission signal. In addition, in the radio frequency module 100, the reception filter 106 constitutes the second electronic component 2 (see FIG. 1) described above. Thus, the second electronic component 2 is a reception circuit component provided in a signal path of a reception signal. In addition, in the radio frequency module 100, the switch 104 constitutes the third electronic component 3 (see FIG. 1) described above. The radio frequency module 100 further includes the plurality of external connection terminals TO as described above. The plurality of external connection terminals TO include an antenna terminal T1, a signal input terminal T2, a signal output terminal T3, a plurality of control terminals T4 (FIG. 7 illustrates only one), a plurality of ground terminals T5 (see FIG. 1), and an output terminal T6. The plurality of ground terminals T5 are terminals to which the ground potential is applied.

The transmission filter 102 is, for example, a filter in which a transmission band of a first communication band is used as a pass band. The first communication band corresponds to a transmission signal passing through the transmission filter 102. The first communication band is, for example, a communication band of the 3GPP LTE standard or a communication band of the 5G NR standard. The first communication band is, but not limited to, a communication band used for communication compatible with frequency division duplex (FDD) as a communication method and may be a communication band used for communication compatible with time division duplex (TDD).

The reception filter 106 is, for example, a filter in which a reception band of the first communication band is used as the pass band. The first communication band is, for example, a communication band of the 3GPP LTE standard or a communication band of the 5G NR standard.

The power amplifier 101 includes an input terminal and an output terminal. The power amplifier 101 amplifies a transmission signal input to the input terminal and outputs the amplified transmission signal from the output terminal. The input terminal of the power amplifier 101 is connected to the signal input terminal T2. The input terminal of the power amplifier 101 is connected to the signal processing circuit 301 of the communication device 300 through the signal input terminal T2. The signal input terminal T2 is a terminal for inputting a radio frequency signal (transmission signal) from an external circuit (for example, the signal processing circuit 301) to the radio frequency module 100. The output terminal of the power amplifier 101 is connected to the switch 104 through the output matching circuit 103 and the transmission filter 102. The power amplifier 101 is, for example, a multi-stage amplifier including a driver stage amplifier and a final stage amplifier. In the power amplifier 101, an input terminal of the driver stage amplifier is connected to the signal input terminal T2, an output terminal of the driver stage amplifier is connected to an input terminal of the final stage amplifier, and an output terminal of the final stage amplifier is connected to the transmission filter 102 through the output matching circuit 103. The power amplifier 101 is not limited to the multi-stage amplifier, and may be, for example, an in-phase combining amplifier or a differential combining amplifier.

The output matching circuit 103 is provided in a signal path between the output terminal of the power amplifier 101 and the transmission filter 102. The output matching circuit 103 is a circuit for performing impedance matching between the power amplifier 101 and the transmission filter 102, and includes, for example, a plurality of inductors and a plurality of capacitors.

The controller 115 controls the power amplifier 101. The controller 115 controls the power amplifier 101 in accordance with, for example, a control signal from the signal processing circuit 301. The controller 115 is connected to the signal processing circuit 301 through a plurality of (for example, 4) control terminals T4. The number of the control terminals T4 is, for example, four. FIG. 7 illustrates only one of the four control terminals T4. The plurality of control terminals T4 are terminals for inputting control signals from an external circuit (for example, the signal processing circuit 301) to the controller 115. The controller 115 controls the power amplifier 101 based on a control signal acquired from the signal processing circuit 301 through the plurality of control terminals T4. The control signal acquired by the controller 115 is a digital signal.

The low-noise amplifier 107 has an input terminal and an output terminal. The low-noise amplifier 107 amplifies the reception signal input to the input terminal and outputs the amplified reception signal from the output terminal. The output terminal of the low-noise amplifier 107 is connected to the signal output terminal T3. The output terminal of the low-noise amplifier 107 is connected to the signal processing circuit 301 through, for example, the signal output terminal T3. The signal output terminal T3 is a terminal for outputting a radio frequency signal (reception signal) from the low-noise amplifier 107 to an external circuit (for example, the signal processing circuit 301).

The input matching circuit 108 is provided in a signal path between the reception filter 106 and the input terminal of the low-noise amplifier 107. The input matching circuit 108 is a circuit for performing impedance matching between the reception filter 106 and the low-noise amplifier 107, and includes, for example, one inductor. The input matching circuit 108 is not limited to a case including one inductor, and may include, for example, a plurality of inductors and a plurality of capacitors.

The switch 104 includes a common terminal 140 and a plurality (for example, two) of selection terminals 141 and 142. In the switch 104, the common terminal 140 is connected to the antenna terminal T1 through the coupler 105. The common terminal 140 and the antenna terminal T1 may be connected to each other through the coupler 105 and a low pass filter in the radio frequency module 100. The selection terminal 141 is connected to the transmission filter 102. The selection terminal 142 is connected to the reception filter 106. The switch 104 is, for example, a switch that can connect one or more of the plurality of selection terminals 141 and 142 to the common terminal 140. In this case, the switch 104 is, for example, a switch that can be connected in a one-to-one manner and a one-to-many manner. The switch 104 is controlled by, for example, the signal processing circuit 301. The switch 104 switches a connection state between the common terminal 140 and the plurality of selection terminals 141 and 142 in accordance with a control signal from an RF signal processing circuit 302 of the signal processing circuit 301. The switch 104 is, for example, a switch integrated circuit (IC).

The coupler 105 is provided in a signal path between the antenna terminal T1 and the common terminal 140 of the switch 104. The coupler 105 detects the signal intensity of a radio frequency signal transmitted through the signal path between the antenna terminal T1 and the common terminal 140 of the switch 104. The coupler 105 has a first terminal, a second terminal, and an output terminal. The first terminal of the coupler 105 is connected to the antenna terminal T1. The second terminal of the coupler 105 is connected to the common terminal 140 of the switch 104. The output terminal of the coupler 105 is connected to the output terminal T6 of the radio frequency module 100. The output terminal of the coupler 105 is connected to the signal processing circuit 301 through, for example, the output terminal T6 of the radio frequency module 100. The output terminal T6 of the radio frequency module 100 is a terminal for outputting a detection signal from the coupler 105 to an external circuit (for example, the signal processing circuit 301).

### (2.2) Structure of Radio Frequency Module

As illustrated in FIG. 1, the radio frequency module 100 includes the mounting board 9, the first electronic component 1, the second electronic component 2, and the third electronic component 3. The first electronic component 1 includes the transmission filter 102 (see FIG. 7). The second electronic component 2 includes the reception filter 106 (see FIG. 7). The third electronic component 3 includes the switch 104 (see FIG. 7). As illustrated in FIG. 7, the radio frequency module 100 further includes the power amplifier 101 and the low-noise amplifier 107. The radio frequency module 100 further includes the output matching circuit 103 and the input matching circuit 108. The radio frequency module 100 further includes the coupler 105. As illustrated in FIG. 1, the radio frequency module 100 further includes the plurality of external connection terminals TO. The radio frequency module 100 further includes the resin layer 5 (referred to as the first resin layer 5 below), the metal electrode layer 6, and a second resin layer 8. FIG. 1 is a sectional view illustrating a section taken along line X-X of FIG. 2.

An outer edge of the mounting board 9 has a quadrangular shape in plan view in the thickness direction D1 of the mounting board 9. As illustrated in FIG. 1, the mounting board 9 has the first main surface 91 and the second main surface 92 facing each other in the thickness direction D1 of the mounting board 9. Further, the mounting board 9 has an outer peripheral surface 93. The outer peripheral surface 93 of the mounting board 9 includes, for example, four side surfaces that connect the outer edge of the first main surface 91 and the outer edge of the second main surface 92 of the mounting board 9, and does not include the first main surface 91 and the second main surface 92. That is, the mounting board 9 is a multilayer substrate including the plurality of dielectric layers and the plurality of conductive layers. The plurality of dielectric layers and the plurality of conductive layers are laminated in the thickness direction D1 of the mounting board 9. The plurality of conductive layers are formed in a predetermined pattern determined for each layer. Each of the plurality of conductive layers includes one or a plurality of conductor portions in one plane perpendicular to the thickness direction D1 of the mounting board 9. A material of each conductive layer is, for example, copper. The plurality of conductive layers include a ground layer. In the radio frequency module 100, the plurality of ground terminals T5 are electrically connected to the ground layer through a via-conductor and the like of the mounting board 9. The mounting board 9 is, for example, a low temperature co-fired ceramics (LTCC) board. The mounting board 9 is not limited to the LTCC substrate, and may be, for example, a printed wiring board, a high temperature co-fired ceramics (HTCC) substrate, or a resin multilayer substrate.

Further, the mounting board 9 is not limited to the LTCC substrate, and may be, for example, a wiring structural body. The wiring structural body is, for example, a multilayer structural body. The multilayer structural body includes at least one insulating layer and at least one conductive layer. The insulating layer is formed in a predetermined pattern. In a case where the number of insulating layers is plural, the plurality of insulating layers are formed in a predetermined pattern determined for each layer. The conductive layer is formed in a predetermined pattern different from the predetermined pattern of the insulating layer. In a case where the number of conductive layers is plural, the plurality of conductive layers are formed in a predetermined pattern determined for each layer. The conductive layer may include one or a plurality of rewiring portions. In the wiring structural body, a first surface of two surfaces facing each other in the thickness direction of the multilayer structural body is the first main surface 91 of the mounting board 9, and a second surface is the second main surface 92 of the mounting board 9. The wiring structural body may be, for example, an interposer. The interposer may be an interposer using a silicon substrate or may be a substrate having multiple layers.

The first main surface 91 and the second main surface 92 of the mounting board 9 are separated in the thickness direction D1 of the mounting board 9, and intersect with the thickness direction D1 of the mounting board 9. The first main surface 91 of the mounting board 9 is, for example, perpendicular to the thickness direction D1 of the mounting board 9, and may include, for example, a side surface or the like of a conductor portion as a surface that is not perpendicular to the thickness direction D1. In addition, for example, the second main surface 92 of the mounting board 9 is perpendicular to the thickness direction D1 of the mounting board 9, but may include, for example, a side surface of the conductor portion or the like, as a surface that is not perpendicular to the thickness direction D1. Further, the first main surface 91 and the second main surface 92 of the mounting board 9 may be formed with fine unevenness, a recess portion, or a projection portion. For example, assuming a recess portion is formed on the first main surface 91 of the mounting board 9, the inner surface of the recess portion is included in the first main surface 91.

In the radio frequency module 100, a plurality of first circuit components are mounted on the first main surface 91 of the mounting board 9. The plurality of first circuit components include the first electronic component 1 (see FIG. 1), the second electronic component 2 (see FIG. 1), the power amplifier 101 (see FIG. 7), the controller 115 (see FIG. 7), and the coupler 105 (see FIG. 7). In addition, the plurality of first circuit components include the plurality of inductors and the plurality of capacitors of the output matching circuit 103. In addition, the plurality of first circuit components include the inductor of the input matching circuit 108. Each of the plurality of inductors included in the output matching circuit 103 is a surface-mounted electronic component, that is, a chip inductor. Each of the plurality of capacitors included in the output matching circuit 103 is a surface-mounted electronic component, that is, a chip capacitor. The inductor of the input matching circuit 108 is, for example, a chip inductor. The fact that “the first circuit components are mounted on the first main surface 91 of the mounting board 9” means that the first circuit components are disposed on (mechanically connected to) the first main surface 91 of the mounting board 9 and the first circuit components are electrically connected to the (appropriate conductor portion of) mounting board 9.

In the radio frequency module 100, a plurality of second circuit components are mounted on the second main surface 92 of the mounting board 9. The plurality of second circuit components include the third electronic component 3 (see FIG. 1) and the low-noise amplifier 107 (see FIG. 7). The fact that “the second circuit components are mounted on the second main surface 92 of the mounting board 9” means that the second circuit components are disposed on (mechanically connected to) the second main surface 92 of the mounting board 9 and the second circuit components are electrically connected to the (appropriate conductor portion of) mounting board 9.

The first electronic component 1 is a transmission electronic component and includes the transmission filter 102 (see FIG. 7). The first electronic component 1 is mounted on the first main surface 91 of the mounting board 9. The first electronic component 1 has the main surface 11 on the opposite side of the mounting board 9 side and the outer peripheral surface 13. The first electronic component 1 further includes an inclined surface 12 that connects the main surface 11 of the first electronic component 1 and the outer peripheral surface 13 of the first electronic component 1. The outer peripheral surface 13 of the first electronic component 1 does not include the main surface 11 and the inclined surface 12 of the first electronic component 1. In addition, the outer peripheral surface 13 of the first electronic component 1 does not include a surface 14 of the first electronic component 1 on the mounting board 9 side. That is, the outer peripheral surface 13 of the first electronic component 1 is a surface separate from each of the main surface 11, the inclined surface 12, and the surface 14 of the electronic component 1 among the surfaces of the first electronic component 1. In a case where the first electronic component 1 has a polygonal shape in plan view from the thickness direction D1 of the mounting board 9, the outer peripheral surface 13 of the first electronic component 1 includes the same number of side surfaces as the number of sides of the polygonal shape. In a case where the first electronic component 1 has a circular shape in plan view from the thickness direction D1 of the mounting board 9, the outer peripheral surface 13 of the first electronic component 1 includes one side surface. The outer peripheral surface 13 of the electronic component 1 and the side surface included in the outer peripheral surface 13 are outer surfaces of the first electronic component 1 and are surfaces along the thickness direction D1 of the mounting board 9. In a case where the first electronic component 1 has, for example, a quadrangular shape in plan view from the thickness direction D1 of the mounting board 9, the outer peripheral surface 13 of the first electronic component 1 includes four side surfaces of the first electronic component 1. In plan view from the thickness direction D1 of the mounting board 9, the outer edge 10 of the first electronic component 1 has a quadrangular shape (see FIG. 2). In plan view from the thickness direction D1 of the mounting board 9, the outer edge 11A of the main surface 11 of the first electronic component 1 is located on the inner side of the outer edge 10 of the first electronic component 1 (see FIG. 2). In a case where the first electronic component 1 has, for example, a quadrangular shape in plan view from the thickness direction D1 of the mounting board 9, the inclined surface 12 has a quadrangular frame shape in plan view from the thickness direction D1 of the mounting board 9 (see FIG. 2).

The second electronic component 2 is a reception electronic component and includes the reception filter 106 (see FIG. 7). The second electronic component 2 is mounted on the first main surface 91 of the mounting board 9. The second electronic component 2 has a main surface 21 on the opposite side of the mounting board 9 side and an outer peripheral surface 23. The second electronic component 2 further includes an inclined surface 22 that connects the main surface 21 of the second electronic component 2 and the outer peripheral surface 23 of the second electronic component 2. In a case where the second electronic component 2 has, for example, a quadrangular shape in plan view from the thickness direction D1 of the mounting board 9, the outer peripheral surface 23 of the second electronic component 2 includes four side surfaces of the second electronic component 2. The outer peripheral surface 23 of the second electronic component 2 does not include the main surface 21 and the inclined surface 22 of the second electronic component 2. In addition, the outer peripheral surface 23 of the second electronic component 2 does not include a surface 24 of the second electronic component 2 on the mounting board 9 side. In plan view from the thickness direction D1 of the mounting board 9, an outer edge 20 of the second electronic component 2 has a quadrangular shape (see FIG. 2). In plan view from the thickness direction D1 of the mounting board 9, an outer edge 21A of the main surface 21 of the second electronic component 2 is located on the inner side of the outer edge 20 of the second electronic component 2 (see FIG. 2). In a case where the second electronic component 2 has, for example, a quadrangular shape in plan view from the thickness direction D1 of the mounting board 9, the inclined surface 22 has a quadrangular frame shape in plan view from the thickness direction D1 of the mounting board 9 (see FIG. 2).

The third electronic component 3 is an IC chip including the switch 104 (see FIG. 7). The IC chip including the switch 104 is a Si-based IC chip. The third electronic component 3 is mounted on the second main surface 92 of the mounting board 9. In plan view of the third electronic component 3 from the thickness direction D1 of the mounting board 9, an outer edge of the third electronic component 3 has a quadrangular shape. The third electronic component 3 has a main surface 31 on the opposite side of the mounting board 9 side and an outer peripheral surface 33. The third electronic component 3 has a common terminal 140 (see FIG. 7) and a plurality of selection terminals 141 and 142 (see FIG. 7) as a plurality of external terminals. Each of the plurality of external terminals is a conductive bump. The third electronic component 3 is flip-chip mounted on the second main surface 92 of the mounting board 9.

The power amplifier 101 (see FIG. 7) is an IC chip for power amplification. The power amplifier 101 is mounted on the first main surface 91 of the mounting board 9 as described above. In plan view from the thickness direction D1 of the mounting board 9, an outer edge of the power amplifier 101 has a quadrangular shape.

Each of the driver stage amplifier and the final stage amplifier of the power amplifier 101 includes an amplifying transistor. The amplifying transistor is, for example, a heterojunction bipolar transistor (HBT). The amplifying transistor is not limited to the HBT, and may be a bipolar transistor or a field effect transistor (FET). The FET is, for example, a metal-oxide-semiconductor field effect transistor (MOSFET). In a case in which the amplifying transistor is the HBT, the power amplifier 101 is, for example, a GaAs-based IC chip. In a case in which the amplifying transistor is the bipolar transistor or the FET, the power amplifier 101 is, for example, a Si-based IC chip.

The controller 115 (see FIG. 7) is an IC chip having a function of controlling the power amplifier 101. The IC chip is a Si-based IC chip. The controller 115 is mounted on the first main surface 91 of the mounting board 9 as described above. In plan view from the thickness direction D1 of the mounting board 9, an outer edge of the controller 115 has a quadrangular shape.

The coupler 105 (see FIG. 7) is a surface-mounted electronic component and is mounted on the first main surface 91 of the mounting board 9. In plan view from the thickness direction D1 of the mounting board 9, an outer edge of the coupler 105 has a quadrangular shape.

Each of the plurality of inductors of the output matching circuit 103 (see FIG. 7) is the chip inductor as described above. An outer edge of each of the plurality of inductors of the output matching circuit 103 has a quadrangular shape in plan view from the thickness direction D1 of the mounting board 9. Each of the plurality of capacitors of the output matching circuit 103 is the chip capacitor as described above. In plan view from the thickness direction D1 of the mounting board 9, an outer edge of each of the plurality of capacitors of the output matching circuit 103 has a quadrangular shape.

An IC chip including the low-noise amplifier 107 (see FIG. 7) is mounted on the second main surface 92 of the mounting board 9. In plan view from the thickness direction D1 of the mounting board 9, an outer edge of the IC chip including the low-noise amplifier 107 has a quadrangular shape.

The inductor of the input matching circuit 108 (see FIG. 7) is the chip inductor as described above. In plan view from the thickness direction D1 of the mounting board 9, an outer edge of the inductor of the input matching circuit 108 has a quadrangular shape.

The plurality of external connection terminals TO (refer to FIGS. 1 and 7) are disposed at the second main surface 92 of the mounting board 9. The phrase that “the external connection terminal TO is disposed at the second main surface 92 of the mounting board 9” means that the external connection terminal TO is mechanically connected to the second main surface 92 of the mounting board 9 and the external connection terminal TO is electrically connected to the (appropriate conductor portion of) mounting board 9.

The plurality of external connection terminals TO include the antenna terminal T1, the signal input terminal T2, the signal output terminal T3, the plurality of control terminals T4, the plurality of ground terminals T5, and the output terminal T6. The plurality of ground terminals T5 are electrically connected to the ground layer of the mounting board 9. The ground layer is a circuit ground of the radio frequency module 100. The plurality of circuit components (the plurality of first circuit components and the plurality of second circuit components) of the radio frequency module 100 include the circuit component electrically connected to the ground layer.

Materials of the plurality of external connection terminals TO are, for example, metal (for example, copper, copper alloy, or the like). The plurality of external connection terminals TO are not constituent elements of the mounting board 9, but may be constituent elements of the mounting board 9. Each of the plurality of external connection terminals TO is a columnar-shaped electrode (for example, a cylindrical-shaped electrode).

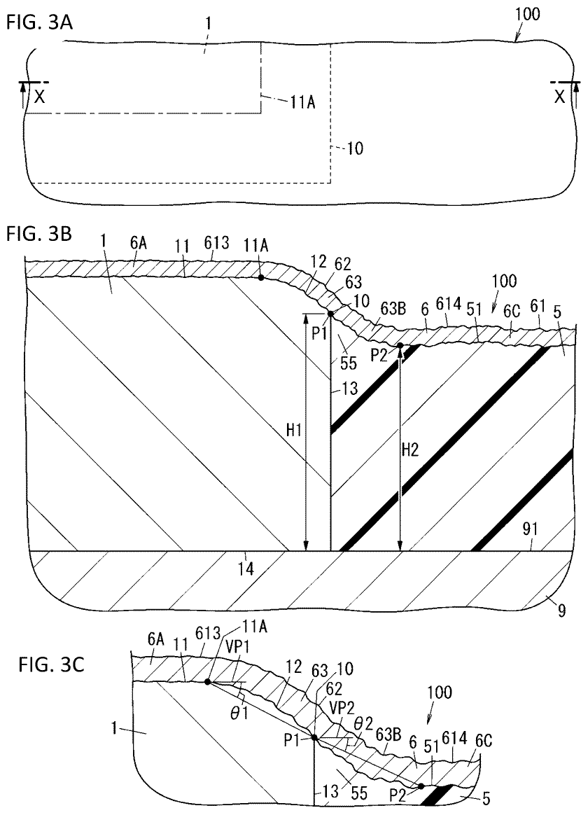

As illustrated in FIGS. 1 and 3B, the first resin layer 5 is disposed at the first main surface 91 of the mounting board 9. The first resin layer 5 contains resin (for example, epoxy resin). The first resin layer 5 may contain a filler in addition to the resin. The first resin layer 5 has electrical insulating properties.

The first resin layer 5 covers the outer peripheral surface 13 of the first electronic component 1. The first resin layer 5 does not cover the main surface 11 and the inclined surface 12 of the first electronic component 1. In addition, the first resin layer 5 covers the outer peripheral surface 23 of the second electronic component 2. As illustrated in FIG. 1, the first resin layer 5 does not cover the main surface 21 and the inclined surface 22 of the second electronic component 2. In addition, the first resin layer 5 covers the power amplifier 101, the plurality of inductors and the plurality of capacitors of the output matching circuit 103, the controller 115, the coupler 105, and the inductor of the input matching circuit 108.

As illustrated in FIG. 1, the metal electrode layer 6 covers the main surface 11 of the first electronic component 1, the inclined surface 12 of the first electronic component 1, the main surface 21 of the second electronic component 2, the inclined surface 22 of the second electronic component 2, the main surface 51 of the first resin layer 5 on the opposite side of the mounting board 9 side, the outer peripheral surface 53 of the first resin layer 5, the outer peripheral surface 93 of the mounting board 9, and the outer peripheral surface 83 of the second resin layer 8. The metal electrode layer 6 is in contact with at least a part of an outer peripheral surface of the ground layer of the mounting board 9. As a result, a potential of the metal electrode layer 6 can be set to be the same as a potential of the ground layer. The metal electrode layer 6 has a multilayer structure in which a plurality of metal layers are laminated. Meanwhile, the present disclosure is not limited thereto and may be one metal layer. The metal layer contains one type or a plurality of types of metals. In a case where the metal electrode layer 6 has a multilayer structure in which a plurality of metal layers are laminated, for example, a first metal layer (for example, a first stainless steel layer), a second metal layer (for example, a Cu layer) on the first metal layer, and a third metal layer (for example, a second stainless steel layer) on the second metal layer. A material of each of the first stainless steel layer and the second stainless steel layer is an alloy including Fe, Ni, and Cr. In addition, the metal electrode layer 6 is, for example, a Cu layer assuming the metal electrode layer is formed of one metal layer.

In the radio frequency module 100, the metal electrode layer 6 is in contact with the entire region of the main surface 11 of the first electronic component 1. In addition, the metal electrode layer 6 is in contact with the entire region of the main surface 21 of the second electronic component 2.

As illustrated in FIG. 1, the second resin layer 8 covers the third electronic component 3, the low-noise amplifier 107 (see FIG. 7), and the outer peripheral surface of each of the plurality of external connection terminals TO. The second resin layer 8 contains resin (for example, epoxy resin). The second resin layer 8 may contain a filler in addition to the resin. The material of the second resin layer 8 may be the same material as the material of the first resin layer 5 or may be a different material. The second resin layer 8 covers the main surface 31 of the third electronic component 3, but the present disclosure is not limited thereto. The second resin layer 8 may not cover the main surface 31 of the third electronic component 3. In addition, the second resin layer 8 does not cover an end surface of the plurality of external connection terminals TO on an opposite side of the mounting board 9 side.

(2.3) Relationship between Electronic Component, Resin Layer, and Metal Electrode Layer

In plan view from the thickness direction D1 of the mounting board 9, the outer edge 11A of the main surface 11 of the electronic component 1 is located on the inner side of the outer edge 10 of the electronic component 1 (see FIGS. 3A and 3B). Here, as illustrated in FIG. 3B, the electronic component 1 has the inclined surface 12 (also referred to as the first inclined surface 12 below) that connects the main surface 11 of the electronic component 1 and the outer peripheral surface 13 of the electronic component 1. The resin layer 5 covers the outer peripheral surface 13 of the electronic component 1, but does not cover the main surface 11 and the first inclined surface 12 of the electronic component 1. The metal electrode layer 6 is disposed across the main surface 11 of the electronic component 1, the first inclined surface 12 of the electronic component 1, and the main surface 51 of the resin layer 5.

As illustrated in FIGS. 1 and 3B, the metal electrode layer 6 has a main surface 61 on an opposite side of the mounting board 9 side. As illustrated in FIG. 3B, the main surface 61 of the metal electrode layer 6 includes a third main surface 613 of the metal electrode layer 6 on an opposite side of the first main surface 11 side of the electronic component 1, a fourth main surface 614 of the metal electrode layer 6 on an opposite side of the first main surface 51 side of the resin layer 5, and a second inclined surface 62 of the metal electrode layer 6 on an opposite side of the first inclined surface 12 side of the electronic component 1. The second inclined surface 62 faces the first inclined surface 12 of the electronic component 1 in a thickness direction of an inclined portion 63 including the second inclined surface 62 in the metal electrode layer 6. The second inclined surface 62 has a shape along the first inclined surface 12. The shape along the first inclined surface 12 means a shape reflecting the shape of the first inclined surface 12.

As illustrated in FIG. 3B, in the radio frequency module 100, the main surface 11 and the first inclined surface 12 of the first electronic component 1 are rough surfaces. In other words, in the radio frequency module 100, fine unevenness is formed at each of the main surface 11 and the first inclined surface 12 of the first electronic component 1. In addition, in the radio frequency module 100, the main surface 51 of the resin layer 5 is a rough surface. In other words, in the radio frequency module 100, fine unevenness is formed at the main surface 51 of the resin layer 5. The main surface 51 of the resin layer 5 is in a state of being rougher than each of the main surface 11 and the first inclined surface 12 of the electronic component 1. In the metal electrode layer 6, a surface roughness of a region 6A overlapping the main surface 11 of the first electronic component 1 is different from a surface roughness of a region 6C overlapping the main surface 51 of the resin layer 5. In addition, in the metal electrode layer 6, a surface roughness of a region 6B (see FIG. 1) overlapping the main surface 21 of the second electronic component 2 is different from the surface roughness of the region 6C overlapping the main surface 51 of the resin layer 5. The surface roughness is an arithmetic average roughness Ra defined in JIS B 0601:2001. The surface roughness can be measured, for example, by using a shape analysis laser microscope (for example, VK-X120 manufactured by KEYENCE CORPORATION) and obtained by measuring a surface in a range of 200 μm×100 μm with a filter type Gaussian. The shape analysis laser microscope used for measuring the surface roughness is not limited to VK-X120 manufactured by Keyence Corporation, and may be any laser microscope capable of shape analysis, for example, VK-X3000 series manufactured by Keyence Corporation. VK-X3000 series manufactured by Keyence Corporation is a white light interferometric laser microscope. In the metal electrode layer 6, the surface roughness of the region 6A overlapping the main surface 11 of the first electronic component 1 is, for example, 0.7 μm, and the surface roughness of the region 6C overlapping the main surface 51 of the resin layer 5 is, for example, 1.2 μm.

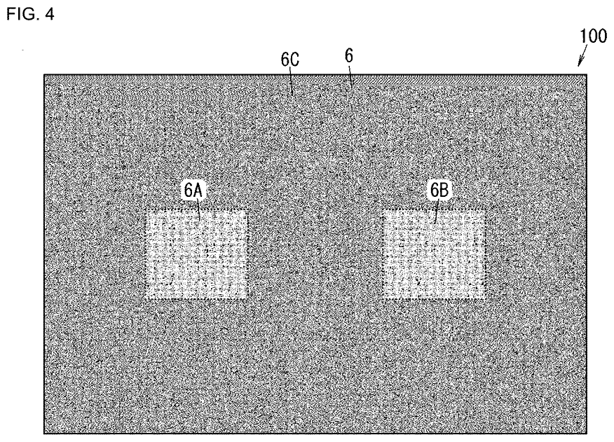

In addition, in the radio frequency module 100, for example, as illustrated in FIG. 4, in plan view from the thickness direction D1 of the mounting board 9, a color of the region where the electronic component 1 is present is different from a color of the region where the electronic component 1 is not present. In the radio frequency module 100, in plan view from the thickness direction D1 of the mounting board 9, the brightness of the color of the region where the electronic component 1 is present is higher than the brightness of the color of the region where the electronic component 1 is not present.

The inclined portion 63 of the metal electrode layer 6 including the second inclined surface 62 includes a portion 63B located on the side of the outer peripheral surface 13 of the electronic component 1, as illustrated in FIG. 3B. The shortest distance H2 between the inclined portion 63 and the first main surface 91 of the mounting board 9 is shorter than the shortest distance H1 between the first inclined surface 12 of the electronic component 1 and the first main surface 91 of the mounting board 9. In a case where the first main surface 91 of the mounting board 9 has unevenness, a plane that is perpendicular to the thickness direction D1 of the mounting board 9 and includes at least a part of the first main surface 91 of the mounting board 9 is defined as a reference plane, the shortest distance between the inclined portion 63 and the reference plane is defined as the above-described shortest distance H2, and the shortest distance between the first inclined surface 12 of the electronic component 1 and the reference plane is defined as the above-described shortest distance H1. A part 55 of the resin layer 5 is interposed between the outer peripheral surface 13 of the electronic component 1 and the portion 63B of the inclined portion 63. As illustrated in FIG. 3C, an inclination angle θ2 of the portion 63B of the inclined portion 63 of the metal electrode layer 6 is smaller than an inclination angle θ1 of the first inclined surface 12 of the electronic component 1. The inclination angle θ1 of the first inclined surface 12 of the electronic component 1 is an angle formed by a straight line linking the outer edge 11A of the main surface 11 of the electronic component 1 and the outer edge 10 of the electronic component 1 and a virtual plane VP1 perpendicular to the thickness direction D1 of the mounting board 9 in a sectional SEM image obtained by viewing the electronic component 1, the resin layer 5, and the metal electrode layer 6 of the radio frequency module 100 in section. The inclination angle θ2 of the portion 63B of the inclined portion 63 of the metal electrode layer 6 is related to the surface of the inclined portion 63 on the mounting board 9 side and is an angle formed by a straight line linking a first end point P1 closest to the outer edge 10 of the electronic component 1 and a second end point P2 on an opposite side of the first end point P1 and a virtual plane VP2 perpendicular to the thickness direction D1 of the mounting board 9 in the sectional SEM image described above. The first end point P1 and the second end point P2 may be, for example, two inflection points of a curve obtained by approximating a curve corresponding to a surface of the inclined portion 63 on the mounting board 9 side in the sectional SEM image by the least squares method. The inclination angle θ1 of the first inclined surface 12 of the electronic component 1 is, for example, 2 degrees or more and 45 degrees or less, and is more preferably 2 degrees or more and 20 degrees or less from the viewpoint of suppressing an occurrence of disconnection of the metal electrode layer 6. The inclination angle θ2 of the portion 63B of the inclined portion 63 of the metal electrode layer 6 is, for example, 2 degrees or more and 45 degrees or less, and is preferably 2 degrees or more and 20 degrees or less from the viewpoint of suppressing the occurrence of disconnection of the metal electrode layer 6. An inclination angle of the second inclined surface 62 of the metal electrode layer 6 is the same as the inclination angle θ1 of the first inclined surface 12 of the electronic component 1. Here, the “same” is not limited to only a case of being exactly the same, and the inclination angle of the second inclined surface 62 of the metal electrode layer 6 may be, for example, a value in a range of 97% or more and 103% or less of the inclination angle θ1 of the first inclined surface 12 of the electronic component 1. The inclination angle of the second inclined surface 62 of the metal electrode layer 6 is an angle formed by a straight line linking the first end point and the second end point of the second inclined surface 62 of the metal electrode layer 6 and the virtual plane VP1 in the sectional SEM image.

In the radio frequency module 100, the first inclined surface 12 of the electronic component 1 and the main surface 51 of the resin layer 5 are flush with each other. The phrase that the first inclined surface 12 of the electronic component 1 and the main surface 51 of the resin layer 5 are flush with each other means that there is no step between the inclined surface 12 of the electronic component 1 and the main surface 51 of the resin layer 5 in a sectional SEM image obtained by viewing the electronic component 1, the resin layer 5, and the metal electrode layer 6 in the radio frequency module 100 in section. However, the present disclosure is not limited to a case in which there is no step between the inclined surface 12 of the electronic component 1 and the main surface 51 of the resin layer 5, and for example, a deviation equal to or less than the maximum height roughness of the main surface 51 of the resin layer 5 is allowed. A direction in which the radio frequency module 100 is viewed in section is a direction perpendicular to one side surface among the four side surfaces of the outer peripheral surface 13 of the electronic component 1, but the direction may not be strictly perpendicular to the one side surface. The maximum height roughness of the main surface 51 of the resin layer 5 is a value measured from an SEM image assuming a section of the radio frequency module 100 is observed with an SEM. The maximum height roughness is a sum of the maximum value of a peak height and the maximum value of a valley depth of the main surface 51 of the resin layer 5 in the SEM image. That is, the maximum height roughness is a peak-to-valley value of the unevenness on the main surface 51 of the resin layer 5.

### (2.4) Structure of Electronic Component

The electronic component 1 is a transmission electronic component and includes the transmission filter 102 (see FIG. 7). The transmission filter 102 is, for example, a ladder filter and includes a plurality of (for example, four) series arm resonators and a plurality of (for example, three) parallel arm resonators. The transmission filter 102 is, for example, an acoustic wave filter. Here, in the acoustic wave filter, for example, each of a plurality of series arm resonators and a plurality of parallel arm resonators is configured with an acoustic wave resonator. The acoustic wave filter is, for example, a surface acoustic wave filter that uses surface acoustic waves. In the surface acoustic wave filter, each of the plurality of series arm resonators and the plurality of parallel arm resonators is, for example, a surface acoustic wave (SAW) resonator.

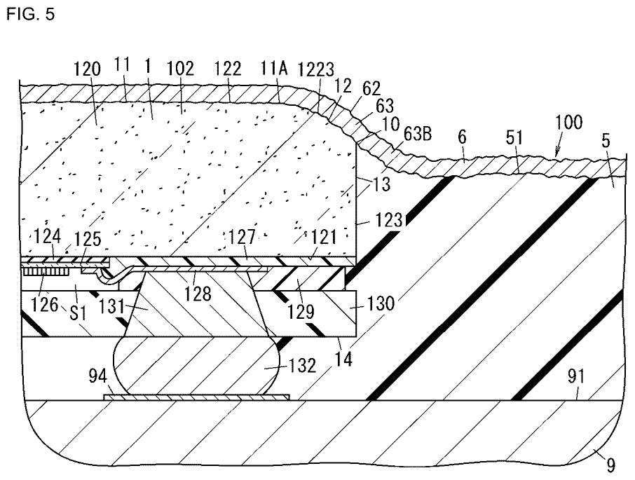

As illustrated in FIG. 5, the transmission filter 102 includes a silicon substrate 120, a low acoustic velocity film 124 formed on the silicon substrate 120, a piezoelectric layer 125 formed on the low acoustic velocity film 124, and a plurality (for example, seven) of interdigital transducer (IDT) electrodes 126 formed on the piezoelectric layer 125. In FIG. 5, only one IDT electrode 126 among the plurality of IDT electrodes 126 is visible. The silicon substrate 120 has a first main surface 121 and a second main surface 122 that face each other in a thickness direction of the silicon substrate 120, and an outer peripheral surface 123. In addition, the silicon substrate 120 further includes an inclined surface 1223 that connects the second main surface 122 and the outer peripheral surface 123. In the electronic component 1, the second main surface 122 of the silicon substrate 120 constitutes the main surface 11 of the electronic component 1, the outer peripheral surface 123 of the silicon substrate 120 constitutes a part of the outer peripheral surface 13 of the electronic component 1, and the inclined surface 1223 of the silicon substrate 120 constitutes the first inclined surface 12 of the electronic component 1. In addition, the transmission filter 102 includes an insulating layer 127, a plurality of wiring electrodes 128, a spacer layer 129, a cover member 130, a plurality of through-electrodes 131, and a plurality of external terminals 132. In FIG. 5, only one external terminal 132 among the plurality of external terminals 132 is visible. Similarly, in FIG. 5, only one wiring electrode 128 among the plurality of wiring electrodes 128 is visible. Similarly, in FIG. 5, only one through-electrode 131 among the plurality of through-electrodes 131 is visible.

The low acoustic velocity film 124 is formed at the first main surface 121 of the silicon substrate 120. The material of the piezoelectric layer 125 is, for example, lithium niobate or lithium tantalate. The low acoustic velocity film 124 is a film in which an acoustic velocity of a bulk wave propagating through the low acoustic velocity film 124 is lower than an acoustic velocity of a bulk wave propagating through the piezoelectric layer 125. The material of the low acoustic velocity film 124 is, for example, silicon oxide, but is not limited to silicon oxide, and may be at least one material selected from the group consisting of tantalum oxide and compounds obtained by adding fluorine, carbon, or boron to silicon oxide. In the silicon substrate 120, a bulk wave propagating through the silicon substrate 120 has a higher acoustic velocity than an acoustic velocity of an acoustic wave propagating through the piezoelectric layer 125. Here, the bulk wave propagating the silicon substrate 120 is the bulk wave having the lowest acoustic velocity among the plurality of bulk waves propagating the silicon substrate 120.

A piezoelectric substrate including the silicon substrate 120, the low acoustic velocity film 124, and the piezoelectric layer 125 may further include a high acoustic velocity film provided between the silicon substrate 120 and the low acoustic velocity film 124. The high acoustic velocity film is a film in which an acoustic velocity of a bulk wave propagating through the high acoustic velocity film is higher than an acoustic velocity of an acoustic wave propagating through the piezoelectric layer 125. A material of the high acoustic velocity film is, for example, silicon nitride, but is not limited to silicon nitride, and may be obtained from at least one type of material selected from the group consisting of diamond-like carbon, aluminum nitride, silicon carbide, silicon nitride, silicon oxynitride, silicon, sapphire, lithium tantalate, lithium niobate, crystal, zirconia, cordierite, mullite, steatite, forsterite, magnesia, and diamond.

A thickness of the piezoelectric layer 125 is, for example, equal to or less than 3.5λ, assuming λ is a wavelength of an acoustic wave determined by an electrode finger period of the IDT electrode 126. A thickness of the low acoustic velocity film 124 is, for example, equal to or less than 2.0λ.

The piezoelectric substrate may include, for example, an adhesion layer interposed between the low acoustic velocity film 124 and the piezoelectric layer 125. The adhesion layer is made of, for example, resin (epoxy resin and polyimide resin). In addition, the piezoelectric substrate may include a dielectric film between the low acoustic velocity film 124 and the piezoelectric layer 125, on the piezoelectric layer 125, or below the low acoustic velocity film 124.

The material of the plurality of IDT electrodes 126 is Al (aluminum), Cu (copper), Pt (platinum), Au (gold), Ag (silver), Ti (titanium), Ni (nickel), Cr (chromium), Mo (molybdenum), W (tungsten), Ta (tantalum), Mg (magnesium), Fe (iron), or an alloy in which any one of these metals is used as a main component. In addition, the plurality of IDT electrodes 126 may have a structure in which a plurality of metal films formed of these metals or the alloy are laminated. In the transmission filter 102, each of the plurality of IDT electrodes 126 is included in the constituent element of the SAW resonator among a plurality of SAW resonators.

The insulating layer 127 has electrical insulating properties. The material of the insulating layer 127 is, for example, an epoxy resin or polyimide. The insulating layer 127 is formed on the first main surface 91 of the silicon substrate 120 along the outer edge of the first main surface 91. The insulating layer 127 covers an outer peripheral surface of the low acoustic velocity film 124 and an outer peripheral surface of the piezoelectric layer 125.

The plurality of wiring electrodes 128 are connected to a circuit portion including the plurality of IDT electrodes 126. The material of the plurality of wiring electrodes 128 is, for example, Al, Cu, Pt, Au, Ag, Ti, Ni, Cr, Mo, W, Ta, Mg, Fe, or an alloy in which any one of these metals is a main component.

The spacer layer 129 is formed on the insulating layer 127. The spacer layer 129 is formed along the outer edge of the silicon substrate 120 in plan view. In plan view from the thickness direction of the silicon substrate 120, the spacer layer 129 has a rectangular frame shape. The spacer layer 129 surrounds a plurality of IDT electrodes 126 in plan view from the thickness direction of the silicon substrate 120. The spacer layer 129 has electrical insulating properties. The material of the spacer layer 129 is epoxy resin, polyimide, or the like.

The cover member 130 has a flat plate shape. The cover member 130 is disposed on the spacer layer 129 to face the silicon substrate 120 in the thickness direction of the silicon substrate 120. The cover member 130 overlaps the plurality of IDT electrodes 126 in the thickness direction of the silicon substrate 120 and is spaced from the plurality of IDT electrodes 126 in the thickness direction of the silicon substrate 120. The cover member 130 has electrical insulating properties. The material of the cover member 130 is epoxy resin, polyimide, or the like. The transmission filter 102 has a space S1 surrounded by the silicon substrate 120, the spacer layer 129, and the cover member 130. A gas is put into the space S1. The gas is air, an inert gas (for example, a nitrogen gas), or the like.

The plurality of external terminals 132 are exposed from the cover member 130. Each of the plurality of external terminals 132 is connected to one of the plurality of wiring electrodes 128 overlapping in the thickness direction of the silicon substrate 120 with one of the plurality of through-electrodes 131 overlapping in the thickness direction of the silicon substrate 120 interposed therebetween. In the radio frequency module 100, the plurality of external terminals 132 of the transmission filter 102 constitute the plurality of external terminals of the first electronic component 1.

The first electronic component 1 is connected to the first main surface 91 of the mounting board 9 through a plurality of external terminals. The phrase of “being connected to the first main surface 91 of the mounting board 9 by the plurality of external terminals” means that the plurality of external terminals of the first electronic component 1 are directly bonded to the first main surface 91 of the mounting board 9, and are mechanically and electrically connected to the plurality of conductor portions of the mounting board 9, which overlap the first electronic component 1 in the thickness direction D1 of the mounting board 9. FIG. 5 illustrates one conductor portion 94 to which one external terminal among the plurality of external terminals of the first electronic component 1 is connected in the mounting board 9. The upper surface and the side surface of the conductor portion 94 illustrated in FIG. 5 are a part of the first main surface 91 of the mounting board 9.

### (3) Manufacturing Method of Radio Frequency Module

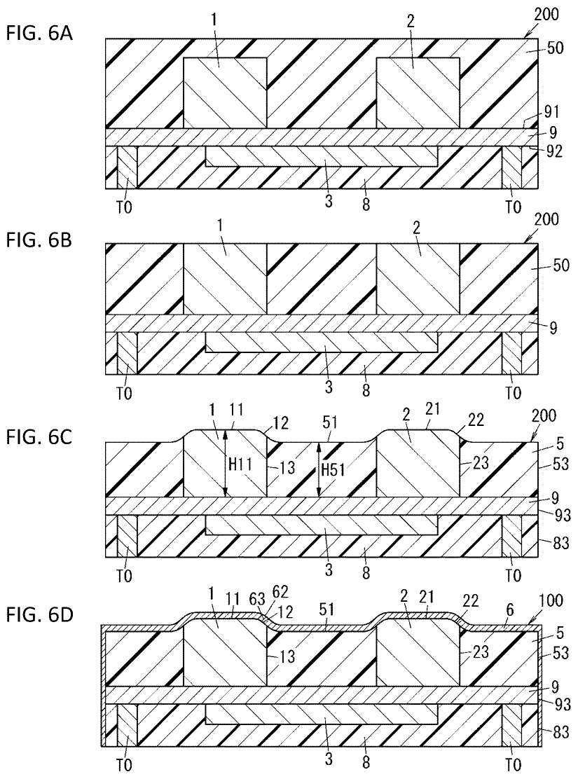

As a manufacturing method of the radio frequency module 100, for example, a manufacturing method including a first step, a second step, and a third step can be adopted. The manufacturing method of the radio frequency module 100 will be described below with reference to FIGS. 6A to 6D.

In the first step, a mounting structural body 200 is prepared (see FIG. 6A). The mounting structural body 200 includes a mounting board 9 having a first main surface 91 and a second main surface 92 that face each other, an electronic component 1 disposed at the first main surface 91 of the mounting board 9, and a resin structural body 50 that is disposed at the first main surface 91 of the mounting board 9 and covers the electronic component 1. The mounting structural body 200 includes a plurality of first circuit components mounted on the first main surface 91 of the mounting board 9 and a plurality of second circuit components mounted on the second main surface 92 of the mounting board 9, similar to the radio frequency module 100. The plurality of first circuit components include the first electronic component 1 and the second electronic component 2 as described above. A thickness of the first electronic component 1 in the mounting structural body 200 is thicker than a thickness of the first electronic component 1 in the radio frequency module 100. In addition, the first electronic component 1 in the mounting structural body 200 does not have the inclined surface 12 of the electronic component 1 in the radio frequency module 100. In addition, the thickness of the second electronic component 2 in the mounting structural body 200 is thicker than the thickness of the second electronic component 2 in the radio frequency module 100. In addition, the second electronic component 2 in the mounting structural body 200 does not have the inclined surface 22 of the second electronic component 2 in the radio frequency module 100. The resin structural body 50 is a structure which is a base for the first resin layer 5. The material of the resin structural body 50 is the same as the material of the first resin layer 5. In addition, the thickness of the resin structural body 50 is thicker than the thickness of the first electronic component 1 and the thickness of the second electronic component 2 in the mounting structural body 200. The mounting structural body 200 further includes a third electronic component 3, a plurality of external connection terminals TO, and a second resin layer 8, which are disposed at the second main surface 92 of the mounting board 9.

In the second step, the mounting structural body 200 is ground from the side of the resin structural body 50 opposite to the mounting board 9 side by the blast processing to expose the main surface 11 of the electronic component 1 on the opposite side of the mounting board 9 side and to form a resin layer 5 formed by a part of the resin structural body 50 (see FIG. 6C). Examples of the blast processing include sand blasting, shot blasting, and wet blasting. The second step is a step of grinding the mounting structural body 200 from the side of the mounting board 9 in the resin structural body 50 opposite to the mounting board 9 side by blast processing to expose the first electronic component 1 (see FIG. 6B), and further grinding the mounting structural body 200 by blast processing (that is, grinding the resin structural body 50, the first electronic component 1, and the second electronic component 2), thereby forming the first resin layer 5 as illustrated in FIG. 6C and thinning the first electronic component 1 and the second electronic component 2. In the second step, in a case where the mounting structural body 200 is ground by the blast processing, an etching rate of a portion of the first electronic component 1 to be ground by the blast processing is slower than the etching rate of the resin structural body 50, and for example, is about half of the etching rate of the resin structural body 50. In other words, the etching rate of the resin structural body 50 is, for example, about twice the etching rate of (the silicon substrate 120 of the transmission filter 102 included in) the first electronic component 1. In the manufacturing method of the radio frequency module 100, by performing the second step, the inclined surface 12 of the first electronic component 1 is formed, and the inclined surface 22 of the second electronic component 2 is formed.

In the second step, the first electronic component 1 and the resin structural body 50 are ground such that an inclined surface 12 connecting the main surface 11 and the outer peripheral surface 13 of the electronic component 1 is formed in the electronic component 1, and the shortest distance H51 between the main surface 51 of the first resin layer 5 on an opposite side of the mounting board 9 side and the mounting board 9 is shorter than the shortest distance H11 between the main surface 11 of the electronic component 1 and the mounting board 9. In a case where the first main surface 91 of the mounting board 9 has unevenness, a plane that is perpendicular to the thickness direction D1 of the mounting board 9 and includes at least a part of the first main surface 91 of the mounting board 9 is defined as a reference plane, the shortest distance between the main surface 11 of the electronic component 1 and the reference plane is defined as the shortest distance H11 described above, and the shortest distance between the main surface 51 of the first resin layer 5 on the opposite side of the mounting board 9 side and the reference plane is defined as the shortest distance H51 described above. A difference between the shortest distance H11 and the shortest distance H51 is, for example, 0.5 μm or more and 40 μm or less, and is more preferably 1 μm or more and 25 μm or less.

In the second step, as illustrated in FIG. 6C, the mounting structural body 200 is ground such that the inclined surface 12 of the first electronic component 1 and the main surface 51 of the first resin layer 5 are flush with each other. In the second step, the main surface 11 and the inclined surface 12 of the first electronic component 1, the main surface 21 and the inclined surface 22 of the second electronic component 2, and the main surface 51 of the first resin layer 5 are roughened by grinding the first electronic component 1, the second electronic component 2, and the first resin layer 5. The surface roughness of each of the main surface 11 of the first electronic component 1, the inclined surface 12 of the first electronic component 1, the main surface 21 of the second electronic component 2, the inclined surface 22 of the second electronic component 2, and the main surface 51 of the first resin layer 5 can be changed by process conditions of the blast processing. In addition, each of the inclination angle θ1 (see FIG. 3C) of the first inclined surface 12 and the inclination angle θ2 (see FIG. 3C) of the portion 63B of the inclined portion 63 can be changed by process conditions of the blast processing.

In the third step, as illustrated in FIG. 6D, a metal electrode layer 6 covering the electronic component 1 and the resin layer 5 is formed. More specifically, in the third step, the metal electrode layer 6 that covers the main surface 11 and the inclined surface 12 of the electronic component 1, the main surface 51 and the outer peripheral surface 53 of the resin layer 5, and the outer peripheral surface 93 of the mounting board 9 is formed. The metal electrode layer 6 formed in the third step also covers the main surface 21 and the inclined surface 22 of the second electronic component 2 and the outer peripheral surface 83 of the second resin layer 8. In the third step, the metal electrode layer 6 is formed to have an inclined portion 63 along the inclined surface 12 of the electronic component 1. In the third step, for example, the metal electrode layer 6 is formed by a sputtering method. In the third step, the metal electrode layer 6 is formed by, but not limited to, the sputtering method, and the metal electrode layer 6 may be formed by, for example, a vapor deposition method.

In the manufacturing method of the radio frequency module 100, the first step and the second step may be performed on a structural body that includes a plurality of mounting structural bodies 200 and that allows a large number of the mounting structural bodies 200 to be taken. In this case, for example, a structural body that can be taken in a large number after the second step may be isolated into a plurality of mounting structural bodies 200, and then the third step may be performed.

### (3) Communication Device

As illustrated in FIG. 7, the communication device 300 includes the radio frequency module 100 and the signal processing circuit 301. The signal processing circuit 301 is connected to the radio frequency module 100.

The communication device 300 further includes the antenna 310. The communication device 300 further includes a circuit board on which the radio frequency module 100 is mounted. The circuit board is, for example, a printed wiring board. The circuit board has a ground electrode to which a ground potential is applied.

The signal processing circuit 301 includes, for example, an RF signal processing circuit 302 and a baseband signal processing circuit 303. The RF signal processing circuit 302 is, for example, a radio frequency integrated circuit (RFIC) and performs signal processing on a radio frequency signal. The RF signal processing circuit 302 performs signal processing, such as upconversion, on the radio frequency signal (transmission signal) output from the baseband signal processing circuit 303, and outputs the radio frequency signal on which the signal processing is performed. In addition, the RF signal processing circuit 302 performs signal processing, such as downconversion, on the radio frequency signal (reception signal) output from the radio frequency module 100, and outputs the radio frequency signal on which the signal processing is performed to the baseband signal processing circuit 303. The baseband signal processing circuit 303 is, for example, a baseband integrated circuit (BBIC). The baseband signal processing circuit 303 generates an I-phase signal and a Q-phase signal from the baseband signal. The baseband signal is, for example, an audio signal, an image signal, and the like input from the outside. The baseband signal processing circuit 303 performs IQ modulation processing by combining the I-phase signal and the Q-phase signal, and outputs a transmission signal. In this case, the transmission signal is generated as a modulation signal (IQ signal) by amplitude modulation of a carrier wave signal of a predetermined frequency in a period longer than a period of the carrier wave signal. The reception signal processed by the baseband signal processing circuit 303 is used, for example, as an image signal for image display or as an audio signal for a call by the user of the communication device 300. The radio frequency module 100 transmits a radio frequency signal (reception signal and transmission signal) between the antenna 310 and the RF signal processing circuit 302 of the signal processing circuit 301.

The plurality of electronic components that configure the signal processing circuit 301 may be mounted on, for example, the above-described circuit board, or may be mounted on a circuit board (second circuit board) different from the circuit board (first circuit board) on which the radio frequency module 100 is mounted.

### (5) Effects

### (5.1) Radio Frequency Module

The radio frequency module 100 according to the embodiment includes the mounting board 9, the electronic component 1, the resin layer 5, and the metal electrode layer 6. The mounting board 9 has a first main surface 91 and a second main surface 92 that face each other. The electronic component 1 is disposed at the first main surface 91 of the mounting board 9. The electronic component 1 has a main surface 11 on an opposite side of the mounting board 9 side and an outer peripheral surface 13. The resin layer 5 is disposed at the first main surface 91 of the mounting board 9. The resin layer 5 covers at least a part of the outer peripheral surface 13 of the electronic component 1. The metal electrode layer 6 covers the main surface 11 of the electronic component 1 and a main surface 51 of the resin layer 5 on an opposite side of the mounting board 9 side. In plan view from a thickness direction D1 of the mounting board 9, an outer edge 11A of the main surface 11 of the electronic component 1 is located on an inner side of an outer edge 10 of the electronic component 1. The electronic component 1 further has an inclined surface 12. The inclined surface 12 connects the main surface 11 of the electronic component 1 and the outer peripheral surface 13 of the electronic component 1. The metal electrode layer 6 is disposed across the main surface 11 of the electronic component 1, the inclined surface 12 of the electronic component 1, and the main surface 51 of the resin layer 5.

With the radio frequency module 100 according to the embodiment, it is possible to improve the heat dissipation properties and the shielding properties. More specifically, in the radio frequency module 100 according to the embodiment, since the metal electrode layer 6 is disposed across the main surface 11 of the electronic component 1, the inclined surface 12 of the electronic component 1, and the main surface 51 of the resin layer 5, it is possible to increase a contact area between the metal electrode layer 6 and the electronic component 1 and to improve adhesion between the metal electrode layer 6 and the electronic component 1. As a result, in the radio frequency module 100, heat generated in the electronic component 1 is likely to be dissipated to the metal electrode layer 6 from the main surface 11 and the inclined surface 12 of the electronic component 1, and it is possible to suppress the deterioration of the characteristics of the electronic component 1 by improving the heat dissipation properties. In addition, in the radio frequency module 100 according to the embodiment, since the metal electrode layer 6 is disposed across the main surface 11 of the electronic component 1, the inclined surface 12 of the electronic component 1, and the main surface 51 of the resin layer 5, it is possible to suppress an occurrence of a situation in which the thickness of a portion of the metal electrode layer 6 in contact with a surface other than the main surface 11 of the electronic component 1 is thinner than the thickness of a portion of the metal electrode layer 6 in contact with the main surface 11. As a result, with the radio frequency module 100, it is possible to improve the heat dissipation properties and the shielding properties, and to suppress the deterioration of the characteristics of the electronic component 1.

In addition, in the radio frequency module 100 according to the embodiment, the main surface 61 of the metal electrode layer 6 on the opposite side of the mounting board 9 side includes the third main surface 613 which is on the side opposite to the main surface 11 side of the electronic component 1 in the metal electrode layer 6, a fourth main surface 614 which is on the side opposite to the main surface 51 side of the resin layer 5 in the metal electrode layer 6, and a second inclined surface 62 which faces the first inclined surface 12 being the inclined surface 12 of the electronic component 1. As a result, in the radio frequency module 100, it is possible to improve the uniformity of the thickness of the metal electrode layer 6 and to further improve the heat dissipation properties and the shielding properties.

In the radio frequency module 100, the temperature of the transmission electronic component tends to be more likely to increase in temperature than the reception electronic component. For example, in the radio frequency module 100, the temperature during the operation of the transmission filter 102 is higher than the temperature during the operation of the reception filter 106, and the transmission filter 102 tends to be more likely to increase in temperature than the reception filter 106. In the radio frequency module 100, since the first electronic component 1 includes the transmission filter 102, it is possible to suppress the temperature rise of the transmission filter 102 and to suppress the deterioration of the characteristics of the transmission filter 102 and the characteristics of the radio frequency module 100.

### (5.2) Manufacturing Method of Radio Frequency Module

The manufacturing method of the radio frequency module 100 according to the embodiment includes the first step, the second step, and the third step. In the first step, the mounting structural body 200 is prepared. The mounting structural body 200 includes a mounting board 9 having a first main surface 91 and a second main surface 92 that face each other, an electronic component 1 disposed at the first main surface 91 of the mounting board 9, and a resin structural body 50 that is disposed at the first main surface 91 of the mounting board 9 and covers the electronic component 1. In the second step, the mounting structural body 200 is ground from the side of the resin structural body 50 opposite to the mounting board 9 side by the blast processing to expose the main surface 11 of the electronic component 1 on the opposite side of the mounting board 9 side and to form a resin layer 5 formed by a part of the resin structural body 50. In the third step, the metal electrode layer 6 that covers the electronic component 1 and the resin layer 5 is formed. In the second step, the electronic component 1 and the resin structural body 50 are ground such that an inclined surface 12 connecting the main surface 11 and the outer peripheral surface 13 of the electronic component 1 is formed in the electronic component 1, and the shortest distance H51 between the main surface 51 of the resin layer 5 on an opposite side of the mounting board 9 side and the mounting board 9 is shorter than the shortest distance H11 between the main surface 11 of the electronic component 1 and the mounting board 9.

According to the manufacturing method of the radio frequency module 100 according to the embodiment, it is possible to improve the heat dissipation properties and the shielding properties.

### (5.3) Communication Device

The communication device 300 according to the embodiment includes the radio frequency module 100 and the signal processing circuit 301. As a result, with the communication device 300 according to the embodiment, it is possible to improve the heat dissipation properties and the shielding properties.

### (6) Other Examples of First Electronic Component in Radio Frequency Module

### (6.1) Another Example 1 of First Electronic Component

The electronic component 1 (first electronic component 1) is not limited to the transmission electronic component, and may be a reception electronic component. For example, in a case where the electronic component 1 is configured by a reception electronic component, a configuration including the reception filter 106 (see FIG. 7) may be adopted.

The reception filter 106 is, for example, a ladder filter and includes a plurality of (for example, four) series arm resonators and a plurality of (for example, three) parallel arm resonators. The reception filter 106 is, for example, an acoustic wave filter. Here, in the acoustic wave filter, for example, each of a plurality of series arm resonators and a plurality of parallel arm resonators is configured with an acoustic wave resonator. The acoustic wave filter is, for example, a surface acoustic wave filter that uses surface acoustic waves. In the surface acoustic wave filter, each of the plurality of series arm resonators and the plurality of parallel arm resonators is, for example, an SAW resonator.

The structure of the reception filter 106 will be described below with reference to FIG. 8, but the constituent elements of the electronic component 1 according to Example 1, which are similar to those of the electronic component 1 in the embodiment, are denoted by the same reference signs, and the description thereof will be omitted as appropriate.

For example, as illustrated in FIG. 8, the reception filter 106 includes the piezoelectric substrate 160 and a plurality (for example, seven) of IDT electrodes 166 formed on the piezoelectric substrate 160. In FIG. 8, only one IDT electrode 166 among the plurality of IDT electrodes 166 is visible. The piezoelectric substrate 160 has a first main surface 161 and a second main surface 162 that face each other in a thickness direction of the piezoelectric substrate 160, and an outer peripheral surface 163. In addition, the piezoelectric substrate 160 further includes an inclined surface 164 that connects the second main surface 162 and the outer peripheral surface 163. In the electronic component 1, the second main surface 162 of the piezoelectric substrate 160 constitutes the main surface 11 of the electronic component 1, the outer peripheral surface 163 of the piezoelectric substrate 160 constitutes a part of the outer peripheral surface 13 of the electronic component 1, and the inclined surface 164 of the piezoelectric substrate 160 constitutes the first inclined surface 12 of the electronic component 1. In addition, the reception filter 106 includes the plurality of wiring electrodes 168, the spacer layer 169, the cover member 170, the plurality of through-electrodes 171, and the plurality of external terminals 172. In FIG. 8, only one external terminal 172 among a plurality of external terminals 172 is visible. Similarly, in FIG. 8, only one wiring electrode 168 among the plurality of wiring electrodes 168 is visible. Similarly, in FIG. 8, only one through-electrode 171 among the plurality of through-electrodes 171 is visible.

The piezoelectric substrate 160 is, for example, but not limited to, a lithium tantalate substrate and may be, for example, a lithium niobate substrate.

The spacer layer 169 is formed on the first main surface 161 of the piezoelectric substrate 160. The spacer layer 169 is formed along an outer edge of the piezoelectric substrate 160 in plan view. The spacer layer 169 has a rectangular frame shape in plan view from the thickness direction of the piezoelectric substrate 160. The spacer layer 169 surrounds the plurality of IDT electrodes 166 in plan view from the thickness direction of the piezoelectric substrate 160. The spacer layer 169 has electrical insulating properties. The material of the spacer layer 169 is epoxy resin, polyimide, or the like.

The cover member 170 has a flat plate shape. The cover member 170 is disposed on the spacer layer 169 to face the piezoelectric substrate 160 in the thickness direction of the piezoelectric substrate 160. The cover member 170 overlaps the plurality of IDT electrodes 166 in the thickness direction of the piezoelectric substrate 160 and is spaced from the plurality of IDT electrodes 166 in the thickness direction of the piezoelectric substrate 160. The cover member 170 has electrical insulating properties. The material of the cover member 170 is epoxy resin, polyimide, or the like. The reception filter 106 has a space S2 surrounded by the piezoelectric substrate 160, the spacer layer 169, and the cover member 170. A gas is put into the space S2. The gas is air, an inert gas (for example, a nitrogen gas), or the like.

The plurality of external terminals 172 are exposed from the cover member 170. Each of the plurality of external terminals 172 is connected to one of the plurality of wiring electrodes 168 overlapping in the thickness direction of the piezoelectric substrate 160 with one of the plurality of through-electrodes 171 overlapping in the thickness direction of the piezoelectric substrate 160 interposed therebetween. The plurality of external terminals 172 of the reception filter 106 constitute the plurality of external terminals of the first electronic component 1.

In a case where the first electronic component 1 includes the reception filter 106, in the second step of the manufacturing method of the radio frequency module 100, the etching rate of the resin structural body 50 is, for example, about twice the etching rate of (the piezoelectric substrate 160 of the reception filter 106 included in) the first electronic component 1.

### (6.2) Another Example 2 of First Electronic Component

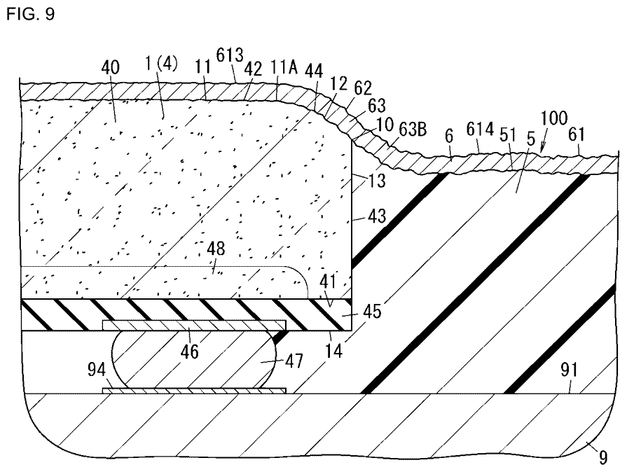

The electronic component 1 (first electronic component 1) according to Example 2 will be described with reference to FIG. 9. The electronic component 1 according to Example 2 is a Si-based IC chip 4. The Si-based IC chip 4 includes, for example, the power amplifier 101 (see FIG. 7). The constituent elements of the electronic component 1 according to Example 2, which are similar to those of the electronic component 1 in the embodiment, are denoted by the same reference signs, and the description thereof will be omitted as appropriate.

The Si-based IC chip 4 includes, for example, a silicon substrate 40, a multilayer structural portion 45 formed on the silicon substrate 40, a circuit portion 48, and a plurality of pad electrodes 46. The silicon substrate 40 has a first main surface 41 and a second main surface 42 that face each other in a thickness direction of the silicon substrate 40, and an outer peripheral surface 43. In addition, the silicon substrate 40 further includes an inclined surface 44 that connects the second main surface 42 and the outer peripheral surface 43. In the Si-based IC chip 4, the second main surface 42 of the silicon substrate 40 constitutes the main surface 11 of the electronic component 1, the outer peripheral surface 43 of the silicon substrate 40 constitutes a part of the outer peripheral surface 13 of the electronic component 1, and the inclined surface 44 of the silicon substrate 40 constitutes the first inclined surface 12 of the electronic component 1. The multilayer structural portion 45 is formed on the first main surface 41 of the silicon substrate 40. The multilayer structural portion 45 includes, for example, a plurality of wiring layers, an interlayer insulating film, and a passivation film. The circuit portion 48 is formed within a region on the first main surface 41 side among the first main surface 41 and the second main surface 42 in the silicon substrate 40 and in the multilayer structural portion 45. In a case in which the Si-based IC chip 4 is the power amplifier 101, the circuit portion 48 includes a plurality of transistors. The plurality of pad electrodes 46 are connected to the circuit portion 48 with the wiring layers and the like of the multilayer structural portion 45 interposed therebetween. The Si-based IC chip 4 may include a silicon on insulator (SOI) substrate instead of the silicon substrate 40.

The Si-based IC chip 4 is mounted on the mounting board 9 by bonding a plurality of pad electrodes 46 to the conductor portion 94 of the mounting board 9 with conductive bumps 47 corresponding to the plurality of pad electrodes 46 one-to-one. A material of the conductive bump 47 is, for example, a solder.

In a case where the first electronic component 1 is the Si-based IC chip 4, in the second step of the manufacturing method of the radio frequency module 100, the etching rate of the resin structural body 50 is, for example, about twice the etching rate of (the silicon substrate 40 of the Si-based IC chip 4 included in) the first electronic component 1.

The Si-based IC chip 4 includes the power amplifier 101, but is not limited thereto. The Si-based IC chip 4 may have a configuration including one or more of the switch 104, the low-noise amplifier 107, or the controller 115.

### (6.3) Another Example 3 of First Electronic Component

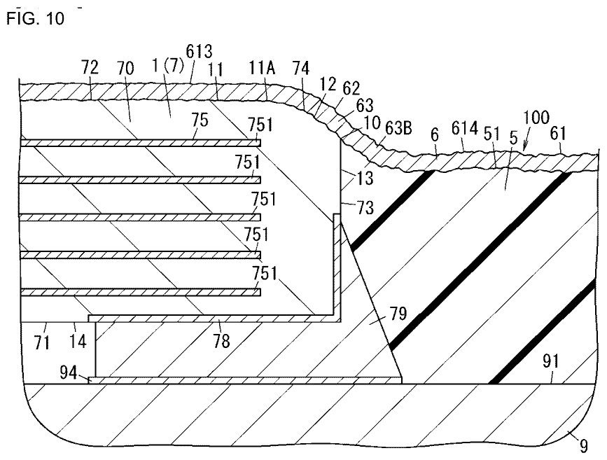

The electronic component 1 (first electronic component 1) according to Example 3 will be described with reference to FIG. 10. The electronic component 1 according to Example 3 is a surface-mounted electronic component. In a case in which the electronic component 1 is configured by a surface-mounted electronic component, the surface-mounted electronic component is, for example, the inductor 7 included in the output matching circuit 103 (see FIG. 7).

The inductor 7 has a rectangular shape. The inductor 7 includes an element body 70, a winding portion 75, and a pair of external terminals 78 (in FIG. 10, only one external terminal 78 is visible). The element body 70 has a first main surface 71 and a second main surface 72 that face each other, and an outer peripheral surface 73. In addition, the element body 70 further has an inclined surface 74 that connects the second main surface 72 and the outer peripheral surface 73. In the inductor 7, the second main surface 72 of the element body 70 constitutes the main surface 11 of the electronic component 1, the outer peripheral surface 73 of the element body 70 constitutes a part of the outer peripheral surface 13 of the electronic component 1, and the inclined surface 74 of the element body 70 constitutes the first inclined surface 12 of the electronic component 1. The material of the element body 70 includes ceramic. The winding portion 75 is disposed in the element body 70. The winding portion 75 is connected between the pair of external terminals 78. The winding portion 75 is a coil conductor portion and has conductivity. A shape of the winding portion 75 is, for example, a spiral shape. The winding portion 75 is, for example, a spiral shape including a plurality (for example, five) of conductor pattern portions 751 and a plurality (for example, four) of via-conductor portions. In the inductor 7, a plurality of conductor pattern portions 751 and a plurality of via-conductor portions are alternately arranged one by one in the thickness direction D1 (see FIG. 1) of the mounting board 9, and one ends of two adjacent conductor pattern portions 751 in the thickness direction D1 of the mounting board 9 are connected to each other through one via-conductor portion. The pair of external terminals 78 are disposed at each of a first end and a second end of the element body 70 in the longitudinal direction (left-right direction in FIG. 10). The material of each external terminal 78 is, for example, Cu or Ag. The material of the winding portion 75 includes, for example, but not limited to, the same material as the pair of external terminals 78. The inductor 7 illustrated in FIG. 10 is a vertically wound inductor, and is mounted on the mounting board 9 such that a winding axis of the winding portion 75 and the thickness direction D1 of the mounting board 9 are parallel to each other. The inductor 7 is mounted on the first main surface 91 of the mounting board 9 in a manner that each of the pair of the external terminals 78 is bonded to the conductor portion 94 of the mounting board 9 by a bonding portion 79 overlapping the external terminal 78. The material of the bonding portion 79 is, for example, a solder.

In a case where the first electronic component 1 is a surface-mounted electronic component (inductor 7), in the second step of the manufacturing method of the radio frequency module 100, the etching rate of the resin structural body 50 is, for example, about twice the etching rate of (the element body 70 included in the inductor 7 constituting) the first electronic component 1.

The inductor 7 is not limited to the vertically wound inductor, and may be a horizontally wound inductor. In addition, the inductor 7 is not limited to the inductor included in the output matching circuit 103 (see FIG. 7), and may be an inductor included in the input matching circuit 108 (see FIG. 7).

The surface-mounted electronic component constituting the first electronic component 1 is not limited to the inductor 7, and may be a capacitor or a coupler.

### Modification Example

The embodiment or the like described above is merely one of various embodiments of the present disclosure. Various modifications of the embodiment or the like described above can be made according to the design or the like as long as the object of the present disclosure can be achieved.

The first inclined surface 12 of the electronic component 1 is not limited to the shape that protrudes toward the metal electrode layer 6 side as illustrated in FIG. 3B in sectional view, and may have, for example, a rounded shape or a linear shape that links the outer edge 11A of the main surface 11 of the electronic component 1 and the outer edge 10 of the electronic component 1 in sectional view.

The second inclined surface 62 in the metal electrode layer 6 is not limited to the shape facing the first inclined surface 12, and may have a shape that does not reflect the shape of the first inclined surface 12.

The electronic component 1 is not limited to the configuration including one transmission filter 102 as illustrated in FIG. 5, and may include a plurality of transmission filters having different pass bands from each other.

In addition, the electronic component 1 is not limited to the configuration including one reception filter 106 as illustrated in FIG. 8, and may include a plurality of reception filters having different pass bands from each other.

In addition, the electronic component 1 may be a bare chip (also referred to as a die) that does not include the spacer layer 129 and the cover member 130 illustrated in FIG. 5. The transmission filter 102 included in the electronic component 1 may have the similar configuration to the reception filter 106 illustrated in FIG. 8.

In addition, the electronic component 1 may be a bare chip (also referred to as a die) that does not include the spacer layer 169 and the cover member 170 illustrated in FIG. 8. The reception filter 106 included in the electronic component 1 may have the similar configuration to the transmission filter 102 illustrated in FIG. 5.

In addition, each of the transmission filter 102 and the reception filter 106 is not limited to a case of being a surface acoustic wave filter, and may be a bulk acoustic wave filter. In the bulk acoustic wave filter, each of a plurality of acoustic wave resonators is a bulk acoustic wave (BAW) resonator. The BAW resonator is, for example, a film bulk acoustic resonator (FBAR) or a solidly mounted resonator (SMR). In a case of the bulk acoustic wave filter, each of the transmission filter 102 and the reception filter 106 includes, for example, a silicon substrate as a substrate.

In addition, each of the transmission filter 102 and the reception filter 106 is not limited to the ladder filter, and may be, for example, a T-type filter or a longitudinally coupled resonator-type surface acoustic wave filter.

In addition, each of the transmission filter 102 and the reception filter 106 may be an acoustic wave filter using a boundary acoustic wave, a plate wave, or the like.

Each of the plurality of external connection terminals TO is not limited to the case of being a columnar-shaped electrode, and may be, for example, a ball-shaped bump. A material of the ball-shaped bump that configures each of the plurality of external connection terminals TO is, for example, gold, copper, solder, and the like.

At least one inductor of the plurality of inductors of the output matching circuit 103 may be an inner layer inductor provided in the mounting board 9. At least one capacitor of the plurality of capacitors of the output matching circuit 103 may be a capacitor incorporated in the mounting board 9. The capacitor incorporated in the mounting board 9 includes a pair of conductor pattern portions facing each other in the thickness direction D1 of the mounting board 9, and a dielectric portion interposed between the pair of conductor pattern portions.

Further, the radio frequency module 100 has a configuration in which a plurality of second circuit components are mounted on the first main surface 91 of the mounting board 9 rather than the second main surface 92, and may not include the second resin layer 8.

The circuit configuration of the radio frequency module 100 is not limited to the example in FIG. 7 described above. The radio frequency module 100 may include, for example, a radio frequency front-end circuit that can be compatible with carrier aggregation and dual connectivity. In addition, the radio frequency module 100 may include, for example, a radio frequency front-end circuit compatible with multi input multi output (MIMO).

In addition, the radio frequency module 100 is not limited to the transmission and reception module including the transmission electronic component and the reception electronic component, may be the transmission module including a transmission electronic component out of the transmission electronic component and the reception electronic component, or may be a reception module including a reception electronic component out of the transmission electronic component and the reception electronic component.

### Aspects

The following aspects are disclosed in the present specification.

A radio frequency module (100) according to a first aspect includes a mounting board (9), an electronic component (1), a resin layer (5), and a metal electrode layer (6). The mounting board (9) has a first main surface (91) and a second main surface (92) facing each other. The electronic component (1) is disposed at the first main surface (91) of the mounting board (9). The electronic component (1) has a main surface (11) on an opposite side of a mounting board (9) side. The resin layer (5) is disposed at the first main surface (91) of the mounting board (9). The resin layer (5) covers at least a part of an outer peripheral surface (13) of the electronic component (1). The metal electrode layer (6) covers the main surface (11) of the electronic component (1) and a main surface (51) of the resin layer (5) on the opposite side of the mounting board (9) side. In plan view from a thickness direction (D1) of the mounting board (9), an outer edge (11A) of the main surface (11) of the electronic component (1) is located on an inner side of an outer edge (10) of the electronic component (1). The electronic component (1) further has an inclined surface (12). The inclined surface (12) connects the main surface (11) of the electronic component (1) and the outer peripheral surface (13) of the electronic component (1). The metal electrode layer (6) is disposed across the main surface (11) of the electronic component (1), the inclined surface (12) of the electronic component (1), and the main surface (51) of the resin layer (5).

With the radio frequency module (100) according to the first aspect, it is possible to improve the heat dissipation properties and the shielding properties.

In a radio frequency module (100) according to a second aspect, in the first aspect, a main surface (61) of the metal electrode layer (6) on the opposite side of the mounting board (9) side includes a third main surface (613) of the metal electrode layer (6) on an opposite side of a main surface (11) side of the electronic component (1), a fourth main surface (614) of the metal electrode layer (6) on an opposite side of a main surface (51) side of the resin layer (5), and a second inclined surface (62) that faces the first inclined surface (12) being the inclined surface (12) of the electronic component (1).

With the radio frequency module (100) according to the second aspect, it is possible to improve the uniformity of the thickness of the metal electrode layer (6) and to further improve the heat dissipation properties and the shielding properties.

In a radio frequency module (100) according to a third aspect, in the second aspect, the metal electrode layer (6) includes an inclined portion (63) including the second inclined surface (62), the inclined portion (63) including a portion (63B) located on a side of the outer peripheral surface (13) of the electronic component (1). A shortest distance (H2) between the inclined portion (63) and the first main surface (91) of the mounting board (9) is shorter than a shortest distance (H1) between the first inclined surface (12) of the electronic component (1) and the first main surface (91) of the mounting board (9). A part (55) of the resin layer (5) is interposed between the outer peripheral surface (13) of the electronic component (1) and the portion (63B) of the inclined portion (63).

With the radio frequency module (100) according to the third aspect, it is possible to improve the heat dissipation properties and the shielding properties as compared with a case in which the part (55) of the resin layer (5) is not interposed between the outer peripheral surface (13) of the electronic component (1) and the portion (63B) of the inclined portion (63).

In a radio frequency module (100) according to a fourth aspect, in the third aspect, an inclination angle (02) of the portion (63B) of the inclined portion (63) of the metal electrode layer (6) is smaller than an inclination angle (01) of the first inclined surface (12) of the electronic component (1).

In a radio frequency module (100) according to a fifth aspect, in the fourth aspect, the inclination angle (02) of the portion (63B) of the inclined portion (63) is 2 degrees or more and 45 degrees or less.

In a radio frequency module (100) according to a sixth aspect, in any one of the first to fifth aspects, the inclined surface (12) of the electronic component (1) and the main surface (51) of the resin layer (5) are flush with each other.

With the radio frequency module (100) according to the sixth aspect, it is possible to improve the uniformity of the thickness of the metal electrode layer (6) and to further improve the heat dissipation properties and the shielding properties.

In a radio frequency module (100) according to a seventh aspect, in any one of the first to sixth aspects, in plan view from the thickness direction (D1) of the mounting board (9), a color of a region where the electronic component (1) is present is different from a color of a region where the electronic component (1) is not present.

With the radio frequency module (100) according to the seventh aspect, a person who views the radio frequency module (100) from the thickness direction (D1) of the mounting board (9) can recognize the region where the electronic component (1) is present.

A radio frequency module (100) according to an eighth aspect is based on any one of the first to sixth aspects. In the metal electrode layer (6), a surface roughness of a region (6A) overlapping the main surface (61) of the electronic component (1) is different from a surface roughness of a region (6C) overlapping the main surface (51) of the resin layer (5).

With the radio frequency module (100) according to the eighth aspect, in plan view from the thickness direction (D1) of the mounting board (9), the color of the region where the electronic component (1) is present is different from the color of the region where the electronic component (1) is not present, and a person who views the radio frequency module (100) from the thickness direction (D1) of the mounting board (9) can recognize the region where the electronic component (1) is present.

In a radio frequency module (100) according to a ninth aspect, in any one of the first to eighth aspects, the electronic component (1) is a transmission electronic component (transmission filter 102; power amplifier 101).

In the radio frequency module (100) according to the ninth aspect, it is likely to dissipate heat generated by the transmission electronic component that is likely to increase in temperature.

In a radio frequency module (100) according to a tenth aspect, in the ninth aspect, the transmission electronic component includes a transmission filter (102) or a power amplifier (101).

In a radio frequency module (100) according to an eleventh aspect, in any one of the first to ninth aspects, the electronic component (1) is a Si-based IC chip (4).

In a radio frequency module (100) according to a twelfth aspect, in the eleventh aspect, the electronic component (1) includes a controller (115) that controls a power amplifier, the power amplifier (101), a low-noise amplifier (107), or a switch (104).

In a radio frequency module (100) according to a thirteenth aspect, in any one of the first to eighth aspects, the electronic component (1) includes a transmission filter (102) or a reception filter (106) including at least one of a lithium tantalate substrate or a lithium niobate substrate.

In a radio frequency module (100) according to a fourteenth aspect, in any one of the first to eighth aspects, the electronic component (1) is a surface-mounted electronic component.

A manufacturing method of a radio frequency module (100) according to a fifteenth aspect includes a first step, a second step, and a third step. In the first step, a mounting structural body (200) is prepared. The mounting structural body (200) includes a mounting board (9) having a first main surface (91) and a second main surface (92) facing each other, an electronic component (1) disposed at the first main surface (91) of the mounting board (9), and a resin structural body (50) that is disposed at the first main surface (91) of the mounting board (9) and covers the electronic component (1). In the second step, the mounting structural body (200) is ground from a side of the resin structural body (50) opposite to a mounting board (9) side by the blast processing to expose a main surface (11) of the electronic component (1) on an opposite side of the mounting board (9) side and to form a resin layer (5) formed by a part of the resin structural body (50). In the third step, a metal electrode layer (6) that covers the electronic component (1) and the resin layer (5) is formed. In the second step, an inclined surface (12) that connects the main surface (11) and an outer peripheral surface (13) of the electronic component (1) is formed at the electronic component (1), and the electronic component (1) and the resin structural body (50) of the mounting structural body (200) are ground such that the shortest distance (H51) between a main surface (51) of the resin layer (5) on the opposite side of the mounting board (9) side and the mounting board (9) is shorter than the shortest distance (H11) between the main surface (11) of the electronic component (1) and the mounting board (9).

With the manufacturing method of the radio frequency module (100) according to the fifteenth aspect, it is possible to improve the heat dissipation properties and the shielding properties.

A manufacturing method of a radio frequency module (100) according to a sixteenth aspect is based on the fifteenth aspect. In the second step, the mounting structural body (200) is ground such that the inclined surface (12) and the main surface (51) of the resin layer (5) are flush with each other.

In a manufacturing method of a radio frequency module (100) according to the sixteenth aspect, it is possible to improve film forming properties of the metal electrode layer (6) in the third step.

A manufacturing method of a radio frequency module (100) according to a seventeenth aspect is based on the fifteenth or sixteenth aspect. In the third step, the metal electrode layer (6) is formed to have an inclined portion (63) along the inclined surface (12) of the electronic component (1).

In the manufacturing method of a radio frequency module (100) according to the seventeenth aspect, it is possible to improve the uniformity of the thickness of the metal electrode layer (6).

A manufacturing method of a radio frequency module (100) according to an eighteenth aspect is based on the seventeenth aspect. In the third step, the metal electrode layer (6) is formed by a sputtering method.

In the manufacturing method of a radio frequency module (100) according to the eighteenth aspect, as compared with a case where the metal electrode layer (6) is formed by a vapor deposition method, it is possible to increase film forming energy of the metal electrode layer (6) and to improve adhesion between the metal electrode layer (6) and each of the first electronic component (1) and the resin layer (5).

A communication device (300) according to a nineteenth aspect includes the radio frequency module (100) according to any one of the first to fourteenth aspects, and a signal processing circuit (301). The signal processing circuit (301) is connected to the radio frequency module (100).

With the communication device (300) according to the nineteenth aspect, it is possible to improve the heat dissipation properties and the shielding properties.

### REFERENCE SIGNS LIST

1 electronic component (first electronic component)
10 outer edge
11 main surface
11A outer edge
12 inclined surface (first inclined surface)
13 outer peripheral surface
2 second electronic component
21 main surface
21A outer edge
22 inclined surface
23 outer peripheral surface
3 third electronic component
31 main surface
33 outer peripheral surface
4 Si-based IC chip
40 silicon substrate
41 first main surface
42 second main surface
43 outer peripheral surface
44 inclined surface
45 multilayer structural portion
46 pad electrode
47 conductive bump
5 resin layer (first resin layer)
50 resin structural body
51 main surface
53 outer peripheral surface
6 metal electrode layer
61 main surface
613 third main surface
614 fourth main surface
62 second inclined surface
63 inclined portion
63B portion
7 inductor (surface-mounted electronic component)
70 element body
71 first main surface
72 second main surface
73 outer peripheral surface
74 inclined surface
75 winding portion
751 conductor pattern portion
79 bonding portion
8 second resin layer
81 main surface
83 outer peripheral surface
9 mounting board
91 first main surface
92 second main surface
93 outer peripheral surface
94 conductor portion
100 radio frequency module
102 transmission filter
120 silicon substrate
121 first main surface
122 second main surface
1223 inclined surface
123 outer peripheral surface
124 low acoustic velocity film
125 piezoelectric layer
126 IDT electrode
128 wiring electrode
129 spacer layer
130 cover member
131 through-electrode
132 external terminal
103 output matching circuit
104 switch
140 common terminal
141, 142 selection terminal
106 reception filter
160 piezoelectric substrate
161 first main surface
162 second main surface
163 outer peripheral surface
164 inclined surface
166 IDT electrode
168 wiring electrode
169 spacer layer
170 cover member
171 through-electrode
172 external terminal
107 low-noise amplifier
108 input matching circuit
115 controller
200 mounting structural body
H1 shortest distance
H2 shortest distance
H11 shortest distance
H51 shortest distance
P1 first end point
P2 second end point
TO external connection terminal
T1 antenna terminal
T2 signal input terminal
T3 signal output terminal
T4 control terminal
T5 ground terminal
T6 output terminal
VP1 virtual plane
VP2 virtual plane
θ1 inclination angle
θ2 inclination angle
300 communication device
301 signal processing circuit
302 RF signal processing circuit
303 baseband signal processing circuit
310 antenna
D1 thickness direction

1. A radio frequency module comprising:
a mounting board that has a first main surface and a second main surface facing each other;
an electronic component that is disposed at the first main surface of the mounting board and has a main surface on an opposite side of a mounting board side and an outer peripheral surface;
a resin layer that is disposed at the first main surface of the mounting board and covers at least a part of the outer peripheral surface of the electronic component; and
a metal electrode layer that covers the main surface of the electronic component and a main surface of the resin layer on the opposite side of the mounting board side, wherein
in plan view from a thickness direction of the mounting board, an outer edge of the main surface of the electronic component is located on an inner side of an outer edge of the electronic component,
the electronic component further has an inclined surface that connects the main surface of the electronic component and the outer peripheral surface of the electronic component, and
the metal electrode layer is disposed across the main surface of the electronic component, the inclined surface of the electronic component, and the main surface of the resin layer.

2. The radio frequency module according to claim 1, wherein
a main surface of the metal electrode layer on the opposite side of the mounting board side includes
a third main surface of the metal electrode layer on an opposite side of a main surface side of the electronic component,
a fourth main surface of the metal electrode layer on an opposite side of a main surface side of the resin layer, and
a second inclined surface that faces a first inclined surface being the inclined surface of the electronic component.

3. The radio frequency module according to claim 2, wherein
the metal electrode layer includes an inclined portion including the second inclined surface, the inclined portion including a portion located on a side of the outer peripheral surface of the electronic component,
a shortest distance between the inclined portion and the first main surface of the mounting board is shorter than a shortest distance between the first inclined surface of the electronic component and the first main surface of the mounting board, and
a part of the resin layer is interposed between the outer peripheral surface of the electronic component and the portion of the inclined portion.

4. The radio frequency module according to claim 3, wherein
an inclination angle of the portion of the inclined portion of the metal electrode layer is smaller than an inclination angle of the first inclined surface of the electronic component.

5. The radio frequency module according to claim 4, wherein
the inclination angle of the portion of the inclined portion is 2 degrees or more and 45 degrees or less.

6. The radio frequency module according to claim 5, wherein
the inclined surface of the electronic component and the main surface of the resin layer are flush with each other.

7. The radio frequency module according to claim 6, wherein
in plan view from the thickness direction of the mounting board, a color of a region where the electronic component is present is different from a color of a region where the electronic component is not present.

8. The radio frequency module according to claim 6, wherein
in the metal electrode layer, a surface roughness of a region overlapping the main surface of the electronic component is different from a surface roughness of a region overlapping the main surface of the resin layer.

9. The radio frequency module according to claim 8, wherein
the electronic component is a transmission electronic component.

10. The radio frequency module according to claim 9, wherein
the transmission electronic component includes a transmission filter or a power amplifier.

11. The radio frequency module according to claim 9, wherein
the electronic component is a Si-based IC chip.

12. The radio frequency module according to claim 11, wherein
the electronic component includes a controller that controls a power amplifier, the power amplifier, a low-noise amplifier, or a switch.

13. The radio frequency module according to claim 8, wherein
the electronic component includes a transmission filter or a reception filter including at least one of a lithium tantalate substrate or a lithium niobate substrate.

14. The radio frequency module according to claim 8, wherein
the electronic component is a surface-mounted electronic component.

15. A manufacturing method of a radio frequency module, comprising:
preparing a mounting structural body including a mounting board having a first main surface and a second main surface facing each other, an electronic component disposed at the first main surface of the mounting board, and a resin structural body that is disposed at the first main surface of the mounting board and covers the electronic component;
grinding the mounting structural body from a side of the resin structural body opposite to a mounting board side by blast processing to expose a main surface of the electronic component on an opposite side of the mounting board side and to form a resin layer formed by a part of the resin structural body; and
forming a metal electrode layer that covers the electronic component and the resin layer, wherein
an inclined surface that connects the main surface and an outer peripheral surface of the electronic component is formed at the electronic component, and
the grinding includes grinding the electronic component and the resin structural body of the mounting structural body such that a shortest distance between a main surface of the resin layer on the opposite side of the mounting board side and the mounting board is shorter than a shortest distance between the main surface of the electronic component and the mounting board.

16. The manufacturing method of a radio frequency module according to claim 15, wherein
the grinding includes grinding the mounting structural body such that the inclined surface and the main surface of the resin layer are flush with each other.

17. The manufacturing method of a radio frequency module according to claim 16, wherein
the forming the metal electrode layer includes forming the metal electrode layer to have an inclined portion along the inclined surface of the electronic component.

18. The manufacturing method of a radio frequency module according to claim 17, wherein
the forming the metal electrode layer includes forming the metal electrode layer by a sputtering method.

19. A communication device comprising:
the radio frequency module according to claim 1; and
a signal processing circuit connected to the radio frequency module.

20. A communication device comprising:
the radio frequency module according to claim 14; and
a signal processing circuit connected to the radio frequency module.
